(19) United States
(12) Patent Application Publication
(10) Pub. No.: US 2023/0247815 A1
(43) Pub. Date: Aug. 3, 2023

(54) WIRE HARNESS

(71) Applicant: SUMITOMO WIRING SYSTEMS, LTD., Yokkaichi-shi, Mie (JP)

(72) Inventor: Katsutoshi IZAWA, Yokkaichi-shi (JP)

(73) Assignee: SUMITOMO WIRING SYSTEMS, LTD., Yokkaichi-shi, Mie (JP)

(21) Appl. No.: 17/799,114

(22) PCT Filed: Feb. 17, 2021
(86) PCT No.: PCT/JP2021/005790

§ 371 Date: Dec. 16, 2022

(30) Foreign Application Priority Data
Feb. 25, 2020 (JP) 2020-029718

(51) Int. Cl. H05K 9/00; H02G 3/30; H01B 7/18; H01B 7/40; H02G 3/04

(52) U.S. Cl. CPC H05K 9/0098; H02G 3/30; H01B 7/18; H01B 7/40; H02G 3/04

(57) ABSTRACT

A wire harness including: a first conductive path including a first wire; a ring-shaped first electromagnetic wave absorber including a first through hole through which the first wire passes; a second conductive path that includes a second wire and is provided side by side with the first conductive path; and a ring-shaped second electromagnetic wave absorber including a second through hole through which the second wire passes, wherein the first electromagnetic wave absorber is provided spaced apart from the second electromagnetic wave absorber in a length direction of the first wire.

### BACKGROUND

This disclosure relates to a wire harness.

Conventionally, wire harnesses, which are provided with wires that electrically connect a plurality of electrical devices and electromagnetic wave absorbing members that absorb electromagnetic waves (electromagnetic noise) emitted from the wires, are known as wire harnesses that are mounted in vehicles such as hybrid vehicles and electric vehicles. As a result of inserting a plurality of wires into a through hole in an electromagnetic wave absorbing member constituted by a ferrite core, the electromagnetic wave absorbing member is provided on an outer circumference of the wires in a wire harness of this type (see JP 2014-130886A, for example).

### SUMMARY

Incidentally, with the above-described wire harness, the larger the electromagnetic waves to be reduced are, the larger the size of the electromagnetic wave absorbing member is. When a plurality of wires are inserted into such a large electromagnetic wave absorbing member, there is a risk that the electromagnetic wave absorbing member may vibrate due to vibration accompanying traveling of the vehicle or the like, for example, and the wires may be shaken by the vibration of the electromagnetic wave absorbing member, and the wires may be damaged.

An exemplary aspect of the disclosure provides a wire harness capable of reducing damage to a wire.

The wire harness of the present disclosure includes: a first conductive path including a first wire; a ring-shaped first electromagnetic wave absorber including a first through hole through which the first wire passes; a second conductive path that includes a second wire and is provided side by side with the first conductive path; and a ring-shaped second electromagnetic wave absorber including a second through hole through which the second wire passes, wherein the first electromagnetic wave absorber is provided spaced apart from the second electromagnetic wave absorber in a length direction of the first wire.

According to the wire harness of the present disclosure, an effect of being able to reduce damage to a wire is exhibited.

### BRIEF DESCRIPTION OF THE DRAWINGS

FIG. 1 is a schematic configuration diagram showing a wire harness according to an embodiment.

FIG. 2 is a schematic cross-sectional view showing a wire harness according to an embodiment.

FIG. 3 is a schematic cross-sectional view (a cross-sectional view taken along line 3-3 in FIG. 2) showing a wire harness according to an embodiment.

FIG. 4 is a schematic transverse cross-sectional view (a cross-sectional view taken along line 4-4 in FIG. 2) showing a wire harness according to an embodiment.

FIG. 5 is a schematic cross-sectional view showing a wire harness according to a modified example.

FIG. 6 is a schematic perspective view showing a wire harness according to a modified example.

FIG. 7 is a schematic transverse cross-sectional view showing a wire harness according to a modified example.

FIG. 8 is a schematic transverse cross-sectional view showing a wire harness according to a modified example.

FIG. 9 is a schematic transverse cross-sectional view showing a wire harness according to a modified example.

FIG. 10 is a schematic cross-sectional view showing a wire harness according to a modified example.

FIG. 11 is a schematic configurational diagram showing a wire harness according to a modified example.

### DETAILED DESCRIPTION OF EMBODIMENTS

### Description of Embodiments

First, embodiments of the present disclosure will be listed and described.

[1] A wire harness of the present disclosure includes: a first conductive path including a first wire; a ring-shaped first electromagnetic wave absorbing member including a first through hole through which the first wire passes; a second conductive path that includes a second wire and is provided side by side with the first conductive path; and a ring-shaped second electromagnetic wave absorbing member including a second through hole through which the second wire passes, in which the first electromagnetic wave absorbing member is provided spaced apart from the second electromagnetic wave absorbing member in a length direction of the first wire.

According to this configuration, the first electromagnetic wave absorbing member is provided on the first wire, and the second electromagnetic wave absorbing member is provided on the second wire. That is, the first electromagnetic wave absorbing member and the second electromagnetic wave absorbing member are individually provided for the first wire and the second wire, respectively. As a result, the electromagnetic waves to be reduced in each of the first electromagnetic wave absorbing member and the second electromagnetic wave absorbing member can be reduced compared to the case where one electromagnetic wave absorbing member is provided for a plurality of wires. For this reason, compared to the case where one electromagnetic wave absorbing member is provided for a plurality of wires, each of the first electromagnetic wave absorbing member and the second electromagnetic wave absorbing member can be made more compact, and the mass of each of the first electromagnetic wave absorbing member and the second electromagnetic wave absorbing member can be reduced. As a result, if the first electromagnetic wave absorbing member and the second electromagnetic wave absorbing member vibrate accompanying traveling of the vehicle or the like, the loads respectively input to the first wire and the second wire from the first electromagnetic wave absorbing member and the second electromagnetic wave absorbing member can be reduced. As a result, it is possible to suppress a case in which the first wire and the second wire is damaged due to the vibration of the first electromagnetic wave absorbing member and the second electromagnetic wave absorbing member.

Here, a “ring” in the present specification includes a circular ring having a circular outer edge shape, a ring having an elliptical or ovoid outer edge shape, a polygonal ring having a polygonal outer edge shape, and a ring having a polygonal outer edge shape with rounded corners, and refers to a ring whose outer shape is composed of any closed shape connected by straight lines or curved lines. A “ring” includes a ring that is a shape having a through hole in a plan view, a shape in which the outer edge shape and the inner circumference shape of the through hole are the same shape, and a shape in which the outer edge shape and the inner circumference shape of the through hole are different from each other. A “ring” includes a ring having a predetermined length extending along the central axis direction in which the central axis passing through the center of the through hole extends, and the length thereof may be large or small. Also, a “ring” in the present specification may be regarded as a ring overall, and includes an object having a notch in a portion thereof, as with a C-shaped object.

[2] It is preferable that the first conductive path further includes a first protective member surrounding an outer circumference of the first electromagnetic wave absorbing member, the second conductive path further includes a second protective member surrounding an outer circumference of the second electromagnetic wave absorbing member, and the first protective member is provided so as to overlap with a portion of the second protective member in a plan view from a first central axis direction in which a central axis of the first through hole extends.

According to this configuration, the first protective member surrounding the outer circumference of the first electromagnetic wave absorbing member is provided so as to overlap with a portion of the second protective member surrounding the outer circumference of the second electromagnetic wave absorbing member in a plan view from the first central axis direction. As a result, it is possible to suppress an increase in the size of the wire harness.

[3] It is preferable that a first fixing member for fixing the first protective member to the second conductive path is further included.

According to this configuration, the first protective member surrounding the outer circumference of the first electromagnetic wave absorbing member is fixed to the second conductive path by the first fixing member. As a result, the first conductive path and the second conductive path provided side by side with the first conductive path are integrated on the outer circumference of the first electromagnetic wave absorbing member. For this reason, the first electromagnetic wave absorbing member provided on the first conductive path can be held by the first conductive path and the second conductive path. As a result, the first electromagnetic wave absorbing member can be held more stably compared to the case where the first electromagnetic wave absorbing member is held by only the first conductive path. Accordingly, it is possible to suppress vibration of the first electromagnetic wave absorbing member caused by vibration accompanying traveling of the vehicle or the like, and it is possible to suppress damage to the first wire caused by vibration of the first electromagnetic wave absorbing member.

[4] It is preferable that a second fixing member for fixing the second protective member to the first conductive path is further included.

According to this configuration, the second protective member surrounding the outer circumference of the second electromagnetic wave absorbing member is fixed to the first conductive path by the second fixing member. As a result, the first conductive path and the second conductive path provided side by side with the first conductive path are integrated on the outer circumference of the second electromagnetic wave absorbing member. For this reason, the second electromagnetic wave absorbing member provided on the second conductive path can be held by the first conductive path and the second conductive path. As a result, the second electromagnetic wave absorbing member can be held more stably compared to the case where the second electromagnetic wave absorbing member is held by only the second conductive path. Accordingly, it is possible to suppress vibration of the second electromagnetic wave absorbing member caused by vibration accompanying traveling of the vehicle or the like, and it is possible to suppress damage to the second wire caused by vibration of the second electromagnetic wave absorbing member.

[5] It is preferable that the first conductive path includes: the first wire; a first outer cover member accommodating the first wire; and a second outer cover member that accommodates the first wire and is provided spaced apart from the first outer cover member in the length direction of the first wire, the first protective member is provided so as to bridge between an outer circumference of the first outer cover member and an outer circumference of the second outer cover member, and the second fixing member fixes the second protective member to the second outer cover member by fastening the second protecting member and the second outer cover member.

According to this configuration, the second protective member and the second outer cover member are fastened by the second fixing member, and the second protective member is fixed to the second outer cover member. For this reason, the second outer cover member is interposed between the second fixing member and the first wire, and the second protective member is interposed between the second fixing member and the second wire. As a result, a case is suppressed in which the second fixing member comes into direct contact with the first wire and the second wire. As a result, it is possible to prevent damage to the first wire and the second wire due to fastening by the second fixing member.

[6] It is preferable that the second conductive path includes: the second wire; a third outer cover member accommodating the second wire; and a fourth outer cover member that accommodates the second wire and is provided spaced apart from the third outer cover member in the length direction of the second wire, the second protective member is provided so as to bridge between an outer circumference of the third outer cover member and an outer circumference of the fourth outer cover member, and the first fixing member fixes the first protective member to the third outer cover member by fastening the first protective member and the third outer cover member.

According to this configuration, the first protective member and the third outer cover member are fastened by the first fixing member, and the first protective member is fixed to the third outer cover member. For this reason, the first protective member is interposed between the first fixing member and the first wire, and the third outer cover member is interposed between the first fixing member and the second wire. As a result, a case is suppressed in which the first fixing member comes into direct contact with the first wire and the second wire. As a result, it is possible to suppress damage to the first wire and the second wire caused by the fastening by the first fixing member.

[7] It is preferable that the first fixing member is a vehicle body fixing clamp for fixing the first conductive path to a vehicle body.

According to this configuration, both the first conductive path and the second conductive path can be fixed to the vehicle body by the first fixing member, which is a vehicle body fixing clamp. For this reason, the number of components can be reduced compared to the case where the clamps are individually provided on both the first conductive path and the second conductive path. Also, the first electromagnetic wave absorbing member can be held more stably by the fixing force of the clamp to the vehicle body. As a result, it is possible to further suppress vibration of the first electromagnetic wave absorbing member caused by vibration accompanying traveling of the vehicle or the like, and it is possible to further suppress damage to the first wire caused by vibration of the first electromagnetic wave absorbing member.

[8] It is preferable that the first conductive path further includes a first covering member that covers the outer circumference of the first wire, the second conductive path further includes a second covering member that covers the outer circumference of the second wire, the first covering member passes through the first through hole while covering the outer circumference of the first wire, and the second covering member passes through the second through hole while covering the outer circumference of the second wire.

According to this configuration, the first wire is inserted through the first through hole of the first electromagnetic wave absorbing member while covered by the first covering member, and the second wire is inserted through the second through hole of the second electromagnetic wave absorbing member while covered by the second covering member. For this reason, it is possible to suppress a case in which the inner circumferential surface of the first through hole comes into direct contact with the outer circumferential surface of the first wire, and it is possible to suppress a case in which the inner circumferential surface of the second through hole comes into direct contact with the outer circumferential surface of the second wire. As a result, it is possible to suitably suppress damage to the first wire and the second wire caused by contact with the inner circumferential surfaces of the first through hole and the second through hole.

[9] It is preferable that the first conductive path further includes a first electromagnetic shielding member that surrounds the outer circumference of the first wire, the second conductive path further includes a second electromagnetic shielding member that surrounds the outer circumference of the second wire, the first electromagnetic shielding member is provided so as to surround the outer circumference of the first electromagnetic wave absorbing member, and the second electromagnetic shielding member is provided so as to surround the outer circumference of the second electromagnetic wave absorbing member.

According to this configuration, the electromagnetic waves emitted from the first wire can be reduced by the first electromagnetic wave absorbing member and the first electromagnetic wave shielding member covering the outer circumference of the first electromagnetic wave absorbing member. Also, the electromagnetic waves emitted from the second wire can be reduced by the second electromagnetic wave absorbing member and the second electromagnetic wave shielding member covering the outer circumference of the second electromagnetic wave absorbing member.

### Detailed Description of Embodiments of the Disclosure

A specific example of a wire harness according to this disclosure will be described with reference to the drawings below. In the drawings, some of the components may be exaggerated or simplified for the sake of description. Also, the dimensional proportions of some parts may differ from their actual proportions. “Parallel” and “orthogonal” in this specification include not only strictly parallel and orthogonal but also generally parallel and orthogonal in a range in which the effects of this embodiment are achieved. Note that the present disclosure is not limited to these examples, but is indicated by the claims, and all changes that fall within the meaning and range of equivalency of the claims are intended to be embraced therein.

### Overall Configuration of Wire Harness 10

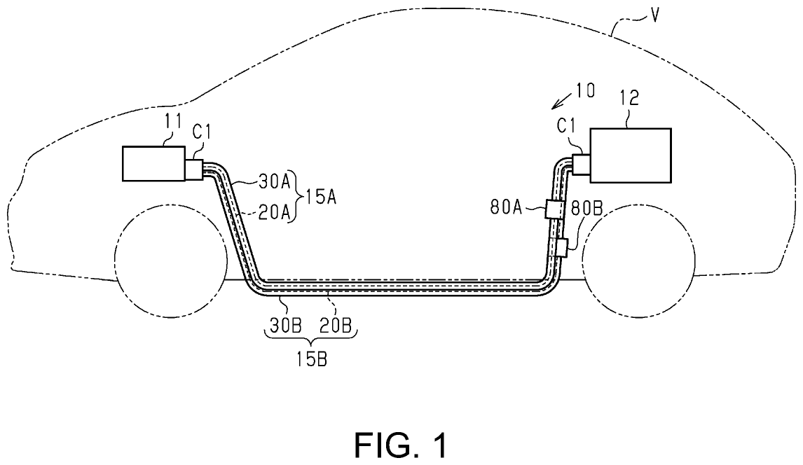

A wire harness 10 shown in FIG. 1 electrically connects two or three or more electric devices (devices). The wire harness 10 electrically connects, for example, an inverter 11 installed at the front of a vehicle V such as a hybrid vehicle or an electric vehicle, and a high-voltage battery 12 installed on the rear side of the vehicle V relative to the inverter 11. The wire harness 10 is routed, for example, so as to pass under a floor of the vehicle V or the like. For example, an intermediate portion of the wire harness 10 in the length direction is routed so as to pass outside the vehicle interior, such as under the floor of the vehicle V. The inverter 11 is connected to a wheel drive motor (not shown) that is a power source for vehicle travel. The inverter 11 generates AC power from the DC power of the high-voltage battery 12, and supplies the AC power to the motor. The high-voltage battery 12 is, for example, a battery capable of supplying a voltage of several hundred volts.

The wire harness 10 includes, for example, a plurality of (in this embodiment, two) conductive paths 15A and 15B, a pair of connectors C1 attached to both ends of the conductive paths 15A and 15B, an electromagnetic wave absorbing member 80A (electromagnetic wave absorber) provided on the conductive path 15A, and an electromagnetic wave absorbing member 80B (electromagnetic wave absorber) provided on the conductive path 15B. The conductive path 15A has, for example, one wire 20A and an outer cover member 30A surrounding the wire 20A. The conductive path 15B has, for example, one wire 20B and an outer cover member 30B surrounding the wire 20B. One end portion of each of the wires 20A and 20B is connected to the inverter 11 via the connector C1, and the other end portion of each of the wires 20A and 20B is connected to the high-voltage battery 12 via the connector C1. Each of the wires 20A and 20B is a high-voltage wire capable of handling a high voltage and a large current. The wire 20A is, for example, a high-voltage wire on the positive side, which is connected to the positive terminal of the high-voltage battery 12. The wire 20B is, for example, a high-voltage wire on the negative side, which is connected to the negative terminal of the high-voltage battery 12. A set of high-voltage circuits is formed by the positive-side wire 20A and the negative-side wire 20B.

### Configuration of Conductive Paths 15A and 15B

The conductive paths 15A and 15B are routed from the inverter 11 to the high-voltage battery 12 in such a manner that, for example, portions in the length direction of the conductive paths 15A and 15B pass under the floor of the vehicle V. The wire harness 10 has, for example, a parallel routing portion that is routed such that the conductive path 15A and the conductive path 15B extend in parallel. The wire harness 10 of the present embodiment is arranged such that the conductive path 15A and the conductive path 15B extend in parallel over the entire length in the length direction of the wire harness 10. That is, the wire harness 10 of the present embodiment is formed such that the parallel routing portion extends over the entire length in the length direction of the wire harness 10. In the parallel routing portion, for example, the conductive path 15A and the conductive path 15B are provided so as to extend parallel to each other. The conductive paths 15A and 15B are each formed so as to be bent two-dimensionally or three-dimensionally according to a set routing path.

### Configuration of Wires 20A and 20B

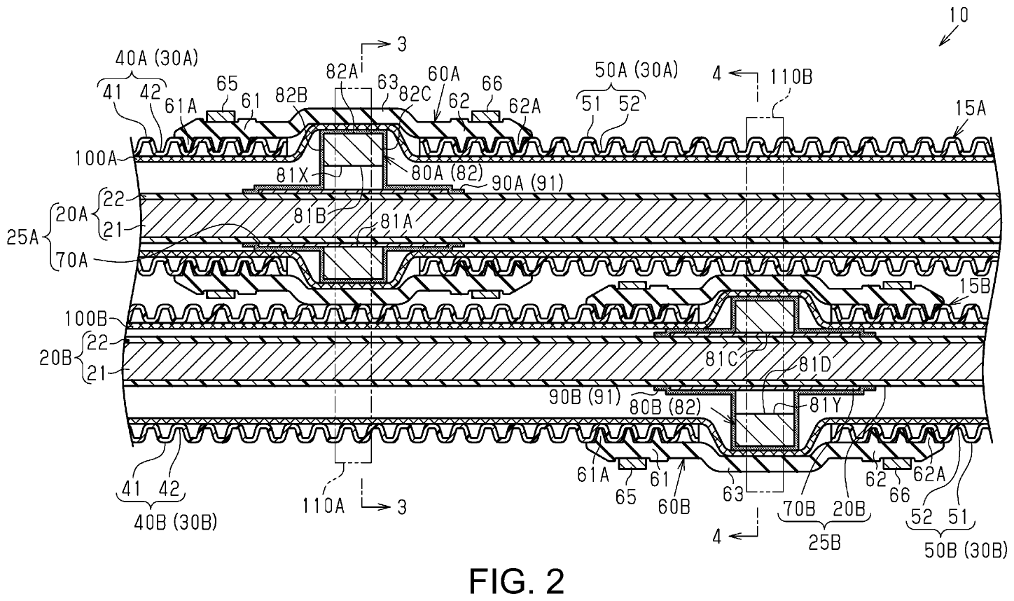

As shown in FIG. 2, each of the wires 20A and 20B is a covered wire having a core wire 21 made of a conductor and an insulating covering 22 covering the outer circumference of the core wire 21. Each of the wires 20A and 20B may be, for example, a shielded wire having an electromagnetic shielding structure, or a non-shielded wire having no electromagnetic shielding structure. Each of the wires 20A and 20B of this embodiment is a non-shielded wire. Each of the wires 20A and 20B is formed in a long shape so as to extend in the front-rear direction of the vehicle V for example. Each of the wires 20A and 20B is formed so as to be bent in a two-dimensional shape or a three-dimensional shape, for example, depending on the routing path of the wire harness 10.

### Configuration of Core Wire 21

As the core wire 21, for example, a twisted wire obtained by twisting a plurality of metal strands together, a columnar conductor constituted by one columnar metal rod that is solid, or a tubular conductor that is hollow can be used. As the core wire 21, for example, a twisted wire, a columnar conductor, and a tubular conductor may be used in combination. Examples of the columnar conductor include a single core wire and a bus bar. The core wire 21 in this embodiment is a twisted wire. A metal material such as a copper-based metal material or an aluminum-based metal material can be used as the material of the core wire 21, for example.

The cross-sectional shape (i.e., a transverse cross-sectional shape) obtained by cutting the core wire 21 along a plane orthogonal to the length direction of the core wire 21 may be any shape. The transverse cross-sectional shape of each core wire 21 is a circular, semicircular, polygonal, square, or flat shape, for example. The transverse cross-sectional shape of the core wire 21 in this embodiment is a circular shape.

### Configuration of Insulating Covering 22

The insulating coverings 22 respectively cover the outer circumferential surfaces of the core wires 21 over the entire circumference in the circumferential direction, for example. The insulating covering 22 is made of an insulating material such as a synthetic resin, for example. It is possible to use a synthetic resin containing polyolefin-based resin as a main component, such as crosslinked polyethylene or crosslinked polypropylene, as the material of the insulating covering 22, for example. Materials of one or more types can be used alone or in combination of two or more as the material of the insulating covering 22. The insulating covering 22 can be formed through, for example, extrusion molding (extrusion coating) performed on the core wire 21.

### Configuration of Outer Cover Members 30A and 30B

The outer cover members 30A and 30B shown in FIG. 1 have a long tubular shape overall. For example, one wire 20A is accommodated in the internal space of the outer cover member 30A. The outer cover member 30A is formed so as to surround the outer circumference of the wire 20A over the entire circumference in the circumferential direction, for example. The outer cover member 30A protects the wire 20A from, for example, flying objects and water droplets. For example, one wire 20B is accommodated in the internal space of the outer cover member 30B. The outer cover member 30B is formed so as to surround the outer circumference of the wire 20B over the entire circumference in the circumferential direction, for example. The outer cover member 30B protects the wire 20B from, for example, flying objects and water droplets.

Metal pipes or resin pipes, resin protectors, flexible corrugated tubes made of resin or the like, waterproof rubber covers, or a combination thereof may be used as the outer cover members 30A and 30B, for example. A metal material such as a copper-based metal material, an iron-based metal material, or an aluminum-based metal material can be used as the material of a metal pipe. A conductive resin material or a resin material that has no conductivity can be used as the material of a resin protector or a resin corrugated tube, for example. It is possible to use a synthetic resin such as polyolefin, polyamide, polyester, or an ABS resin, as this resin material, for example.

As shown in FIG. 2, the outer cover member 30A has, for example, a corrugated tube 40A, a corrugated tube 50A, and a protective member 60A. The outer cover member 30B has, for example, a corrugated tube 40B, a corrugated tube 50B, and a protective member 60B.

A resin material having no conductivity is used as the material of the corrugated tubes 40A, 50A, 40B, and 50B of the present embodiment. As the resin material, for example, synthetic resins such as polyolefin, polyamide, polyester, and ABS resin can be used. As the material of the protective members 60A and 60B, for example, an elastic material having a relatively high hardness can be used. As the elastic material, for example, rubber such as ethylene propylene diene rubber or elastomer can be used.

### Configuration of Corrugated Tubes 40A and 40B

The corrugated tube 40A, for example, has a tubular shape that surrounds the outer circumference of the wire 20A overall. The corrugated tube 40A is provided, for example, so as to surround the outer circumference of the wire 20A over the entire circumference in the circumferential direction. The corrugated tube 40A is provided, for example, so as to surround a portion in the length direction (axial direction) of the wire 20A. The corrugated tube 40B has, for example, a tubular shape that surrounds the outer circumference of the wire 20B overall. The corrugated tube 40B is provided, for example, so as to surround the outer circumference of the wire 20B over the entire circumference in the circumferential direction. The corrugated tube 40B is provided, for example, so as to surround a portion in the length direction (axial direction) of the wire 20B. The corrugated tubes 40A and 40B have an accordion structure in which ring-shaped protrusions 41 and ring-shaped recesses 42 are arranged alternatingly along the length direction thereof. The corrugated tubes 40A and 40B are more flexible than the core wires 21. The corrugated tubes 40A and 40B of the present embodiment are formed in a cylindrical shape.

### Configuration of Corrugated Tubes 50A and 50B

The corrugated tube 50A is provided spaced apart from the corrugated tube 40A, for example, in the length direction of the wire 20A. The corrugated tube 50A has, for example, a tubular shape that surrounds the outer circumference of the wire 20A overall. The corrugated tube 50A is provided, for example, so as to surround the outer circumference of the wire 20A over the entire circumference in the circumferential direction. The corrugated tube 50A is provided, for example, so as to surround a portion in the length direction of the wire 20A. The corrugated tube 50B is provided spaced apart from the corrugated tube 40B, for example, in the length direction of the wire 20B. The corrugated tube 50B has, for example, a tubular shape that surrounds the outer circumference of the wire 20B overall. The corrugated tube 50B is provided, for example, so as to surround the outer circumference of the wire 20B over the entire circumference in the circumferential direction. The corrugated tube 50B is provided, for example, so as to surround a portion in the length direction of the wire 20B. The corrugated tubes 50A and 50B have an accordion structure in which ring-shaped protrusions 51 and ring-shaped recesses 52 are arranged alternatingly along the length direction thereof. The corrugated tubes 50A and 50B are more flexible than the core wire 21. The corrugated tubes 50A and 50B of the present embodiment are formed in a cylindrical shape.

### Configuration of Protective Members 60A and 60B

The protective member 60A is provided, for example, so as to bridge between the outer circumference of the corrugated tube 40A and the outer circumference of the corrugated tube 50A The protective member 60A has, for example, a tubular shape in which both ends in the length direction of the wire 20A are open. The protective member 60B is provided, for example, so as to bridge between the outer circumference of the corrugated tube 40B and the outer circumference of the corrugated tube 50B. The protective member 60B has, for example, a cylindrical shape in which both ends in the length direction of the wire 20B are open. The protective members 60A and 60B of the present embodiment are formed in a cylindrical shape.

### Configuration of Conductive Path 15A

The conductive path 15A has, for example, a wire member 25A and a braided member 100A surrounding the wire member 25A. The wire member 25A has, for example, the wire 20A and a covering member 70A (first cover) that covers the wire 20A. The wire harness 10 includes, for example, an electromagnetic wave absorbing member 80A provided at a portion in the length direction of the wire member 25A and a restricting member 90A that restricts the relative movement of the electromagnetic wave absorbing member 80A with respect to the wire member 25A in the length direction of the wire member 25A

### Configuration of Covering Member 70A

The covering member 70A is formed, for example, so as to cover the outer circumference of the wire 20A at a portion passing through the electromagnetic wave absorbing member 80A The covering member 70A is provided, for example, so as to surround the outer circumference of the wire 20A located between the corrugated tube 40A and the corrugated tube 50A The covering member 70A is provided, for example, so as to surround the outer circumference of the wire 20A exposed from both of the corrugated tubes 40A and 50A The covering member 70A has, for example, a tubular shape that surrounds the outer circumference of the wire 20A overall. The covering member 70A is provided, for example, so as to surround the outer circumference of the wire 20A over the entire circumference in the circumferential direction. For example, one end in the length direction of the covering member 70A is accommodated in the internal space of the corrugated tube 40A, and the other end in the length direction of the covering member 70A is accommodated in the internal space of the corrugated tube 50A. That is, the outer circumference of one end of the covering member 70A is surrounded by the corrugated tube 40A, and the outer circumference of the other end of the covering member 70A is surrounded by the corrugated tube 50A. The outer circumferential dimension of the covering member 70A is set smaller than, for example, the inner circumferential dimension of each of the corrugated tubes 40A and 50A.

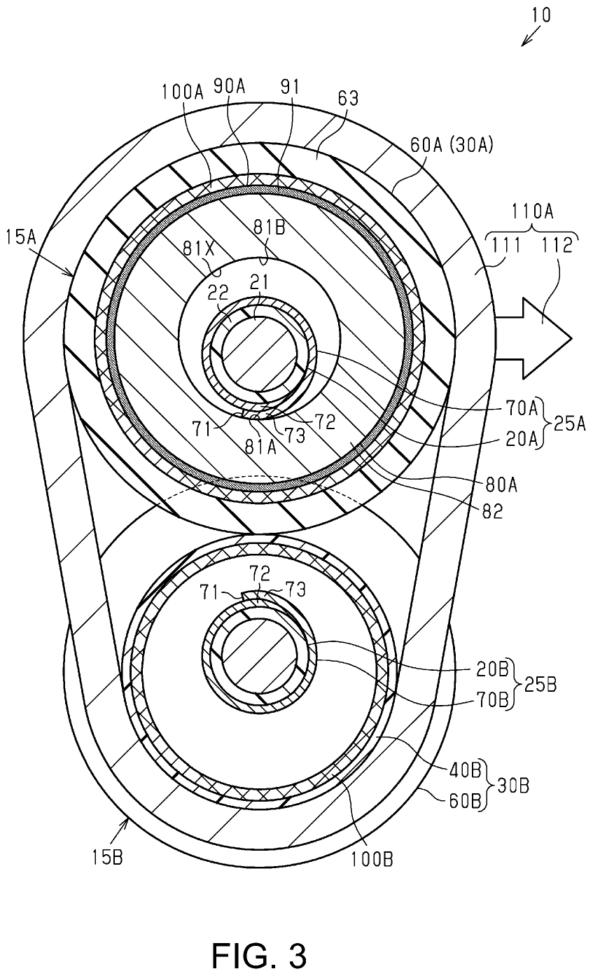

As shown in FIG. 3, for example, the covering member 70A is formed in a sheet shape having a slit 71 extending along the length direction of the wire 20A. The covering member 70A is formed so as to have a tubular shape, for example, by winding a flexible resin sheet in the circumferential direction of the wire 20A. The covering member 70A includes, for example, a first end portion 72 in a first direction (in FIG. 3, the circumferential direction of the wire 20A) intersecting the length direction of the wire 20A, and a second end portion 73 on the opposite side in the first direction from the first end portion 72. The covering member 70A is formed so as to have a tubular shape by, for example, overlapping the first end portion 72 and the second end portion 73 in the radial direction of the wire 20A. The inner circumferential dimension of the covering member 70A can be adjusted to match the outer circumferential dimension of the wire 20A by for example, adjusting the overlapping width of the first end portion 72 and the second end portion 73. The covering member 70A has elasticity according to which it is possible to return from a tubular state of being able to surround the outer circumference of the wire 20A to a sheet state of not surrounding the outer circumference of the wire 20A, for example.

As the material of the covering member 70A, a resin material having no conductivity is used. As the resin material, for example, synthetic resins such as polyethylene terephthalate, polyolefin, polyamide, polyester, and ABS resin can be used. As the covering member 70A, for example, a twist tube can be used. The twist tube is made of, for example, a woven fabric made of polyethylene terephthalate or polyester. The twist tube is formed by, for example, weaving resin fibers, and has a mesh.

### Configuration of Electromagnetic Wave Absorbing Member 80A

As shown in FIG. 2, the electromagnetic wave absorbing member 80A is provided on the outer circumference of the wire 20A located between the corrugated tube 40A and the corrugated tube 50A, for example. For example, the corrugated tube 40A is provided on one side of the electromagnetic wave absorbing member 80A, and the corrugated tube 50A is provided on the other side of the electromagnetic wave absorbing member 80A in the length direction of the wire 20A. The electromagnetic wave absorbing member 80A is provided spaced apart from the corrugated tube 40A in the length direction of the wire 20A, for example. The electromagnetic wave absorbing member 80A is provided spaced apart from the corrugated tube 50A in the length direction of the wire 20A, for example. The electromagnetic wave absorbing member 80A is, for example, exposed from the corrugated tubes 40A and 50A. The electromagnetic wave absorbing member 80A is provided, for example, so as to surround the outer circumference of one wire 20A. The electromagnetic wave absorbing member 80A is provided, for example, so as to surround the outer circumference of the covering member 70A over the entire circumference in the circumferential direction. The electromagnetic wave absorbing member 80A absorbs some of the electromagnetic waves (electromagnetic noise) emitted from the wire 20A, for example.

The electromagnetic wave absorbing member 80A has, for example, a through hole 81X through which one wire 20A passes. The electromagnetic wave absorbing member 80A has a ring shape, for example, due to having the through hole 81X. For example, the electromagnetic wave absorbing member 80A is formed in a ring shape that has the through hole 81X in a plan view from the length direction of the wire 20A, and has a predetermined length by which it extends along a first central axis direction in which the central axis passing through the center of the through hole 81X extends. In the present embodiment, the first central axis direction of the electromagnetic wave absorbing member 80A is set to a direction of extending parallel to the length direction of the wire 20A. Note that in the following description, when the term “first central axis direction” is simply described, it is assumed to mean the first central axis direction of the electromagnetic wave absorbing member 80A.

The through hole 81X is formed, for example, so as to pass through the electromagnetic wave absorbing member 80A in the length direction of the wire 20A. The wire 20A is provided, for example, so as to pass through the through hole 81X. The covering member 70A is provided, for example, so as to pass through the through hole 81X while surrounding the outer circumference of the wire 20A. The inner circumferential surface of the through hole 81X opposes the outer circumferential surface of the wire 20A and the outer circumferential surface of the covering member 70A.

Here, “opposing” in the present specification means that surfaces or members are in front of each other, and encompasses not only a case where they are completely in front of each other, but also a case where they are partially in front of each other. Also, the term “opposing” in the present specification encompasses both a case where a member different from two portions is interposed between the two portions and a case where nothing is interposed between the two portions.

The electromagnetic wave absorbing member 80A of the present embodiment is constituted by only a ring-shaped magnetic core 82. The magnetic core 82 of the present embodiment is formed in a circular ring shape. The magnetic core 82 has, for example, a function of reducing electromagnetic waves emitted from the wire 20A due to being arranged so as to oppose the wire 20A over the entire circumference in the circumferential direction of the wire 20A. For example, the magnetic core 82 absorbs electromagnetic waves emitted from the wire 20A and converts the energy of the electromagnetic waves into mechanical energy such as vibration or thermal energy. As a result, the adverse effect of the electromagnetic waves emitted from the wire 20A on peripheral devices and the like is reduced.

The magnetic core 82 is, for example, a molded body containing a soft magnetic material. Examples of the soft magnetic material include iron (Fe), iron alloys and ferrites. Examples of the iron alloys include a Fe-silicon (Si) alloy and a Fe-nickel (Ni) alloy. As the magnetic core 82, for example, a ferrite core, an amorphous core, or a permalloy core can be used. The ferrite core is made of, for example, soft ferrite exhibiting soft magnetism. Examples of the soft ferrite include a ferrite containing nickel (Ni) and zinc (Zn) and a ferrite containing manganese (Mn) and zinc (Zn). The material of the magnetic core 82 can be appropriately selected, for example, according to the frequency band of the electromagnetic noise to be reduced.

As shown in FIG. 3, the magnetic core 82 of the present embodiment is formed continuously over the entire circumference in the circumferential direction, and is formed in a closed ring shape. That is, the magnetic core 82 of the present embodiment is formed in a structure in which the entirety is connected to form a continuous ring, that is, an endless structure in which the start point and the end point coincide with each other. In other words, no slit that extends along the first central axis direction is formed in the magnetic core 82 of the present embodiment. The magnetic core 82 of this embodiment is constituted by one component. Note that although the magnetic core 82 is constituted by one component in the present embodiment, a plurality of core materials may be combined to form a ring-shaped magnetic core 82. For example, the magnetic core 82 may be formed into a circular ring shape by combining a pair of core materials having semicircular transverse cross sections.

As shown in FIG. 2, the magnetic core 82 includes, for example, an outer circumferential surface 82A extending along the circumferential direction of the magnetic core 82, a side surface 82B that extends along the radial direction of the magnetic core 82 and faces toward the corrugated tube 40A, and a side surface 82C that extends along the radial direction of the magnetic core 82 and faces toward the corrugated tube 50A. The side surfaces 82B and 82C are provided, for example, between the outer circumferential surface 82A and the inner circumferential surface of the through hole 81X. The outer circumferential dimension of the magnetic core 82 is set to be larger than the outer circumferential dimension of the corrugated tubes 40A and 50A, for example. For this reason, the outer circumferential surface 82A of the magnetic core 82 is provided at a position protruding outward in the radial direction relative to the outer circumferential surfaces of the corrugated tubes 40A and 50A.

### Configuration of Restricting Member 90A

The restricting member 90A is provided so as to fix the electromagnetic wave absorbing member 80A to the wire member 25A, for example. The restricting member 90A is provided so as to fix the electromagnetic wave absorbing member 80A to the outer circumference of the covering member 70A, for example.

The restricting member 90A is formed, for example, by winding the tape member 91 around the electromagnetic wave absorbing member 80A and the wire member 25A. The tape member 91 has, for example, a pressure-sensitive adhesive layer on one surface. The tape member 91 is wound around the electromagnetic wave absorbing member 80A, the covering member 70A, and the wire 20A, for example, with the pressure-sensitive adhesive layer facing inward in the radial direction. The tape member 91 is wound around, for example, the outer circumferential surface 82A of the electromagnetic wave absorbing member 80A, the outer circumferential surface of the covering member 70A, and the outer circumferential surface of the wire 20A.

For example, the tape member 91 is continuously wound over a range from the outer circumferential surface 82A of the electromagnetic wave absorbing member 80A to the outer circumferential surface of the wire 20A via the outer circumferential surface of the covering member 70A. Although not shown in the drawings, the tape member 91 has, for example, an overlap winding structure. Here, the overlap winding structure is a structure in which the tape member 91 is spirally wound such that predetermined portions in the width direction of the tape member 91 overlap each other. Note that the width direction of the tape member 91 is a direction extending along the length direction of the wire 20A. As the overlap winding structure, for example, a half-wrap winding structure is preferable. Here, the half-wrap winding structure is a structure in which the tape member 91 is spirally wound so that portions that are approximately halfway in the width direction of the tape member 91 overlap each other.

For example, one end in the length direction of the tape member 91 is accommodated in the internal space of the corrugated tube 40A, and the other end in the length direction of the tape member 91 is accommodated in the internal space of the corrugated tube 50A. That is, the outer circumference of one end of the tape member 91 is surrounded by the corrugated tube 40A, and the outer circumference of the other end of the tape member 91 is surrounded by the corrugated tube 50A.

The tape member 91 covers, for example, the outer circumferential surface 82A of the electromagnetic wave absorbing member 80A so as to fasten the outer circumferential surface 82A inward in the radial direction. The tape member 91 covers, for example, the outer circumferential surface 82A of the electromagnetic wave absorbing member 80A over the entire circumference in the circumferential direction. The electromagnetic wave absorbing member 80A is fixed to the outer circumference of the wire member 25A by, for example, being fastened inward in the radial direction by the tape member 91.

The tape member 91, for example, covers the outer circumferential surface of the covering member 70A such that the outer circumferential surface is fastened inward in the radial direction. The tape member 91 covers, for example, the outer circumferential surface of the covering member 70A such that the outer circumferential surface is fastened in the direction in which the covering member 70A approaches the wire 20A. The covering member 70A is in contact with the outer circumferential surface of the wire 20A, for example, due to being fastened inward in the radial direction by the tape member 91. The tape member 91, for example, covers the outer circumferential surface of the covering member 70A over the entire circumference in the circumferential direction. The tape member 91 has, for example, a function of maintaining the covering member 70A in a tubular state, that is, a function of suppressing the return of the covering member 70A to the sheet state.

The tape member 91, for example, covers the outer circumferential surface of the wire 20A such that the outer circumferential surface is fastened inward in the radial direction. The tape member 91 covers, for example, the outer circumferential surface of the wire 20A over the entire circumference in the circumferential direction.

As shown in FIG. 3, for example, the tape member 91 is wound around the outer circumferential surfaces of the electromagnetic wave absorbing member 80A and the wire member 25A such that the wire member 25A is arranged offset toward a portion in the circumferential direction of the through hole 81X inside the through hole 81X of the electromagnetic wave absorbing member 80A. Here, the inner circumferential surface of the through hole 81X has a first portion 81A, and a second portion 81B arranged at a position that is point-symmetrical to the first portion 81A with respect to the central axis of the through hole 81X. At this time, the wire member 25A is in contact with the first portion 81A and is separated from the second portion 81B inside the through hole 81K For example, a portion of the covering member 70A is in contact with the first portion 81A inside the through hole 81X. The first portion 81A of the present embodiment is a portion provided at a position closer to the conductive path 15B than the second portion 81B in the direction intersecting the first central axis direction of the electromagnetic wave absorbing member 80A. The tape member 91, for example, fixes the electromagnetic wave absorbing member 80A to the outer circumference of the wire member 25A such that the wire member 25A is in contact with the first portion 81A and is separated from the second portion 81B. In other words, the electromagnetic wave absorbing member 80A is fixed to the outer circumferential surface of the wire member 25A by the tape member 91 in a state where the wire member 25A is in contact with the first portion 81A and is offset to the first portion 81A side (in this embodiment, the conductive path 15B side) inside the through hole 81X.

As shown in FIG. 2, for example, the wire member 25A is arranged offset in the same direction, that is, toward the first portion 81A (here, downward in the drawing), over the entire length in the first central axis direction of the through hole 81X. The wire member 25A of the present embodiment is arranged offset to the conductive path 15B side over the entire length in the central axis direction of the through hole 81X. In other words, the tape member 91 is wound around the outer circumferential surfaces of the electromagnetic wave absorbing member 80A and the wire member 25A such that the wire member 25A is arranged offset in the same direction over the entire length in the first central axis direction of the through hole 81X.

### Configuration of Braided Member 100A

The braided member 100A has, for example, a tubular shape that surrounds the outer circumference of the wire 20A overall. The braided member 100A is provided, for example, so as to surround the outer circumference of the wire 20A over approximately the entire length in the length direction of the wire 20A. The braided member 100A is formed, for example, so as to surround the outer circumference of the wire 20A in each of the internal spaces of the corrugated tubes 40A and 50A. The braided member 100A is provided, for example, so as to surround the outer circumference of the end portions of the covering member 70A and the restricting member 90A in each of the internal spaces of the corrugated tubes 40A and 50A In other words, the corrugated tubes 40A and 50A are provided so as to respectively surround the outer circumference of the wire 20A, the covering member 70A, the restricting member 90A, and the braided member 100A. The braided member 100A is formed, for example, so as to surround the outer circumference of the electromagnetic wave absorbing member 80A between the corrugated tube 40A and the corrugated tube 50A. The braided member 100A is formed such that, for example, the outer shape of the portion covering the electromagnetic wave absorbing member 80A is larger than the outer shape of other portions. The braided member 100A is provided, for example, so as to surround the outer circumference of the wire member 25A, the electromagnetic wave absorbing member 80A, and the restricting member 90A in the internal space of the protective member 60A. Here, the restricting member 90A is provided between the electromagnetic wave absorbing member 80A and the braided member 100A, for example, in the direction intersecting the length direction of the wire 20A, that is, in the radial direction of the wire 20A.

As the braided member 100A, a braided member in which a plurality of metal strands are braided or a braided member in which metal strands and resin strands are braided in combination with each other can be used. As the material of the metal strands, for example, a metal material such as a copper-based metal material or an aluminum-based metal material can be used. As the resin strands, for example, reinforcing fibers having excellent insulating properties and shear resistance, such as para-aramid fibers, can be used. Note that both end portions of the braided member 100A are connected to ground (grounded) at, for example, a connector C1 (see FIG. 1), although this is not shown in the drawings.

### Configuration of Protective Member 60A

The protective member 60A is provided, for example, so as to surround the outer circumference of the electromagnetic wave absorbing member 80A. The protective member 60A functions as, for example, a waterproof cover for waterproofing various members arranged inside of the protective member 60A.

The protective member 60A includes, for example, a tubular connection tube portion 61 connected to the outer circumference of the corrugated tube 40A, a tubular connection tube portion 62 connected to the outer circumference of the corrugated tube 50A, and a main body tube portion 63 that is provided between the connection tube portion 61 and the connection tube portion 62. The main body tube portion 63 is formed protruding radially outward from the outer circumference of the other portions, that is, the connection tube portions 61 and 62. The main body tube portion 63 is formed, for example, so as to protrude radially outward from the connection tube portions 61 and 62 over the entire circumference in the circumferential direction of the connection tube portions 61 and 62. The outer circumferential dimension of the main body tube portion 63 is formed to be larger than the outer circumferential dimension of the connection tube portions 61 and 62, for example. The protective member 60A is, for example, a single component formed in one piece by connecting the connection tube portion 61, the main body tube portion 63, and the connection tube portion 62. The connection tube portions 61 and 62 and the main body tube portion 63 of the present embodiment are formed continuously over the entire circumference in the circumferential direction, and are formed in an endless structure in which the start point and the end point coincide with each other. In other words, no slits extending along the length direction of the wire 20A are formed in the connection tube portions 61 and 62 and the main body tube portion 63 of the present embodiment.

In the protective member 60A, for example, the connection tube portion 61 is fitted to the outer circumference of the corrugated tube 40A, and the connection tube portion 62 is fitted to the outer circumference of the corrugated tube 50A.

The connection tube portion 61 is formed in a tubular shape having a size according to which it can be fitted on the outer circumference of the corrugated tube 40A, for example. The connection tube portion 61 of the present embodiment is formed in a cylindrical shape. On the inner circumferential surface of the end portion of the connection tube portion 61, for example, one or a plurality of (here, three) lips 61A that engage with the corrugated tube 40A are formed. Each lip 61A is, for example, formed continuously over the entire circumference of the inner circumferential surface of the connection tube portion 61, and is formed in an endless structure. Each lip 61A is formed, for example, so as to enter a ring-shaped recess 42 of the corrugated tube 40A when the connection tube portion 61 is fitted to the outer circumference of the corrugated tube 40A.

For example, a coupling member 65 is provided on the outer circumferential surface of the connection tube portion 61. As the coupling member 65, for example, a cable tie made of resin or metal, a caulking ring, a tape member, or the like can be used. The connection tube portion 61 is fastened from the outer circumferential side by the coupling member 65 and fixed to the corrugated tube 40A For example, the connection tube portion 61 is fastened from the outer circumferential side by the coupling member 65 until it is in close contact with the corrugated tube 40A in a liquid-tight manner. As a result, it is possible to suppress a case in which water enters the inside of the protective member 60A from between the connection tube portion 61 and the corrugated tube 40A.

The connection tube portion 62 is formed in, for example, a tubular shape having a size that can be fitted to the outer circumference of the corrugated tube 50A. The connection tube portion 62 of the present embodiment is formed in a cylindrical shape. On the inner circumferential surface of the end of the connection tube portion 62, for example, one or more (here, three) lips 62A that engage with the corrugated tube 50A are formed. Each lip 62A is formed continuously over the entire circumference of the inner circumferential surface of the connection tube portion 62, for example, and is formed in an endless structure. Each lip 62A is formed, for example, so as to enter a ring-shaped recess 52 of the corrugated tube 50A when the connection tube portion 62 is fitted to the outer circumference of the corrugated tube 50A.

For example, a coupling member 66 is provided on the outer circumferential surface of the connection tube portion 62. As the coupling member 66, for example, a cable tie made of resin or metal, a caulking ring, a tape member, or the like can be used. The connection tube portion 62 is fastened from the outer circumferential side by the coupling member 66 and is fixed to the corrugated tube 50A. For example, the connection tube portion 62 is fastened from the outer circumferential side by the coupling member 66 until it is in close contact with the corrugated tube 50A in a liquid-tight manner. As a result, it is possible to suppress a case in which water enters the inside of the protective member 60A from between the connection tube portion 62 and the corrugated tube 50A.

For example, one end portion of the main body tube portion 63 is formed continuously in one piece with the connection tube portion 61, and the other end portion is formed continuously in one piece with the connection tube portion 62. The main body tube portion 63 is formed in a tubular shape having a size capable of accommodating, for example, the electromagnetic wave absorbing member 80A. The main body tube portion 63 of the present embodiment is formed in a cylindrical shape. The main body tube portion 63 is formed so as to surround, for example, the electromagnetic wave absorbing member 80A over the entire circumference in the circumferential direction. The main body tube portion 63 is formed so as to surround, for example, the wire member 25A, the electromagnetic wave absorbing member 80A, the restricting member 90A, and the braided member 100A, which are exposed from the corrugated tubes 40A and 50A, over the entire circumference in the circumferential direction.

The inner circumferential surface of the main body tube portion 63 is in contact with, for example, the outer circumferential surface of the braided member 100A. The inner circumferential surface of the braided member 100A is in contact with, for example, the outer circumferential surface of the restricting member 90A. For example, the inner circumferential surface of the braided member 100A is in contact with the outer circumferential surface of the restricting member 90A that covers the outer circumferential surface 82A of the magnetic core 82.

### Configuration of Conductive Path 15B

The conductive path 15B has, for example, a wire member 25B and a braided member 100B surrounding the wire member 25B. The wire member 25B has, for example, a wire 20B and a covering member 70B (second cover) that covers the wire 20B. The wire harness 10 has, for example, an electromagnetic wave absorbing member 80B provided on a portion in the length direction of the wire member 25B and a restricting member 90B that restricts relative movement of the electromagnetic wave absorbing member 80B with respect to the wire member 25B in the length direction of the wire member 25B. Here, the covering member 70B has the same structure as the covering member 70A, the electromagnetic wave absorbing member 80B has the same structure as the electromagnetic wave absorbing member 80A, and the restricting member 90B has the same structure as the restricting member 90A. Also, the braided member 100B has the same structure as the braided member 100A, and the protective member 60B has the same structure as the protective member 60A. For this reason, in the present embodiment, the covering member 70B is denoted by the same reference numerals as the covering member 70A, the electromagnetic wave absorbing member 80B is denoted by the same reference numerals as the electromagnetic wave absorbing member 80A, the restricting member 90B is denoted by the same reference numerals as the restricting member 90A, the protective member 60B is denoted by the same reference numerals as the protective member 60A, and detailed description of each of these elements will be omitted.

### Configuration of Covering Member 70B

The covering member 70B is formed so as to cover the outer circumference of the wire 20B at a portion passing through the electromagnetic wave absorbing member 80B, for example. The covering member 70B is provided so as to surround the outer circumference of the wire 20B located between the corrugated tube 40B and the corrugated tube 50B, for example. The covering member 70B is provided so as to surround the wire 20B exposed from both of the corrugated tubes 40B and 50B, for example. For example, one end in the length direction of the covering member 70B is accommodated in the internal space of the corrugated tube 40B, and the other end in the length direction is accommodated in the internal space of the corrugated tube 50B.

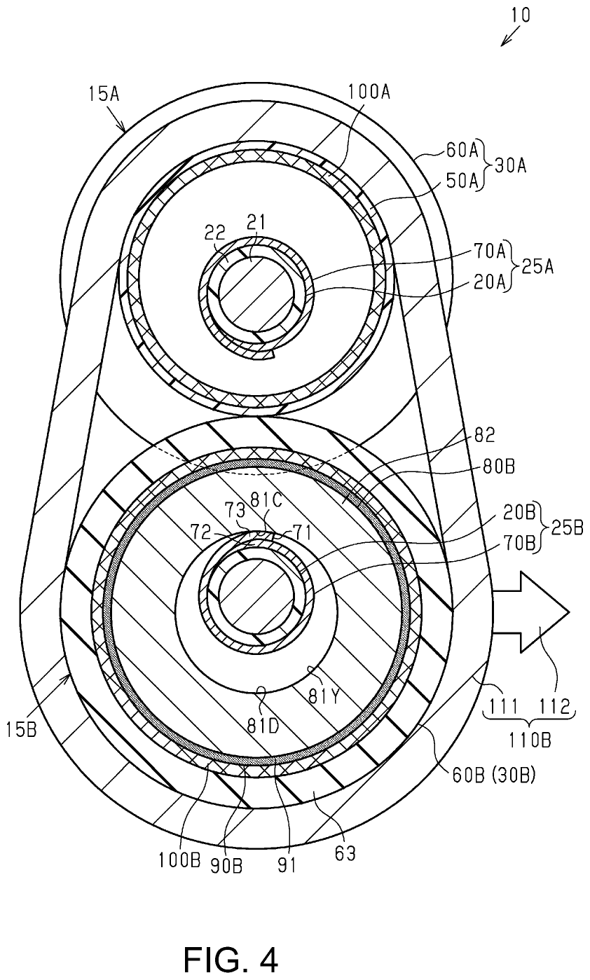

As shown in FIG. 4, the covering member 70B is formed in the form of a sheet having, for example, a slit 71 extending along the length direction of the wire 20B. The covering member 70B has, for example, a first end portion 72 in a first direction (in FIG. 4, the circumferential direction of the wire 20B) intersecting the length direction of the wire 20B, and a second end portion 73 on the opposite side in the first direction from the first end portion 72. The covering member 70B is formed so as to have a tubular shape, for example, by overlapping the first end portion 72 and the second end portion 73 in the radial direction of the wire 20B.

### Configuration of Electromagnetic Wave Absorbing Member 80B

As shown in FIG. 2, the electromagnetic wave absorbing member 80B is, for example, provided on the outer circumference of the wire 20B located between the corrugated tube 40B and the corrugated tube 50B. For example, in the length direction of the wire 20B, the corrugated tube 40B is provided on one side of the electromagnetic wave absorbing member 80B, and the corrugated tube 50B is provided on the other side of the electromagnetic wave absorbing member 80B.

The electromagnetic wave absorbing member 80B is provided, for example, at a position spaced apart from the electromagnetic wave absorbing member 80A in the length direction of the wires 20A and 20B. The electromagnetic wave absorbing member 80B is located, for example, at a position spaced apart from the electromagnetic wave absorbing member 80A by at least twice the length along the first central axis direction of the electromagnetic wave absorbing member 80A in the length direction of the wires 20A and 20B. The electromagnetic wave absorbing member 80B is provided at a position spaced apart from the protective member 60A in the length direction of the wires 20A and 20B, for example.

The electromagnetic wave absorbing member 80B has, for example, a through hole 81Y in a plan view from the length direction of the wire 20B, and is formed in a ring shape having a predetermined length extending along a second central axis direction along which the central axis passing through the center of the through hole 81Y extends. The electromagnetic wave absorbing member 80B of the present embodiment is constituted by only the ring-shaped magnetic core 82. The magnetic core 82 of the electromagnetic wave absorbing member 80B has a function of reducing electromagnetic waves emitted from the wire 20B by being arranged so as to oppose the wire 20B over the entire circumference of the wire 20B in the circumferential direction, for example. The wire 20B is provided so as to pass through the through hole 81Y, for example. The covering member 70B is provided so as to pass through the through hole 81Y while surrounding the outer circumference of the wire 20B, for example. The inner circumferential surface of the through hole 81Y opposes the outer circumferential surface of the wire 20B and the outer circumferential surface of the covering member 70B.

### Configuration of Restricting Member 90B

The restricting member 90B is provided so as to fix the electromagnetic wave absorbing member 80B to the wire member 25B, for example. The restricting member 90B is provided so as to fix the electromagnetic wave absorbing member 80B to the outer circumferential surface of the covering member 70B, for example.

The restricting member 90B is formed, for example, by winding a tape member 91 around the electromagnetic wave absorbing member 80B, the covering member 70B, and the wire 20B. For example, the tape member 91 is continuously wound over a range from the outer circumferential surface 82A of the electromagnetic wave absorbing member 80B to the outer circumferential surface of the wire 20B via the outer circumferential surface of the covering member 70B. Although not shown in the drawings, the tape member 91 has, for example, an overlap winding structure.

As shown in FIG. 4, the tape member 91 is wound around the outer circumferential surfaces of the electromagnetic wave absorbing member 80B and the wire member 25B such that, for example, inside the through hole 81Y of the electromagnetic wave absorbing member 80B, the wire member 25B is arranged offset to a portion in the circumferential direction of the through hole 81Y. Here, the inner circumferential surface of the through hole 81Y has a third portion 81C and a fourth portion 81D that is arranged at a position point-symmetrical to the third portion 81C with respect to the central axis of the through hole 81Y. At this time, the wire member 25B is in contact with the third portion 81C and is separated from the fourth portion 81D inside the through hole 81Y. For example, a portion of the covering member 70B is in contact with the third portion 81C inside the through hole 81Y. The third portion 81C of the present embodiment is a portion provided at a position closer to the conductive path 15A than the fourth portion 81D in the direction intersecting the second central axis direction of the electromagnetic wave absorbing member 80B. The tape member 91 fixes the electromagnetic wave absorbing member 80B to the outer circumference of the wire member 25B such that, for example, the wire member 25B is in contact with the third portion 81C and is separated from the fourth portion 81D. In other words, the electromagnetic wave absorbing member 80B is fixed to the outer circumferential surface of the wire member 25B by the tape member 91 in a state where the wire member 25B is in contact with the third portion 81C inside the through hole 81Y and is offset to the third portion 81C side (in this embodiment, to the conductive path 15A side).

As shown in FIG. 2, for example, the wire member 25B is arranged in the same direction over the entire length in the second central axis direction of the through hole 81Y, that is, offset to the third portion 81C side (here, on the upper side in the drawing). The wire member 25B of the present embodiment is arranged offset to the conductive path 15A side over the entire length in the second central axis direction of the through hole 81Y. In other words, the tape member 91 is wound around the outer circumferential surfaces of the electromagnetic wave absorbing member 80B and the wire member 25B such that the wire member 25B is arranged offset in the same direction over the entire length in the second central axis direction of the through hole 81Y.

### Configuration of Braided Member 100B

The braided member 100B has, for example, a tubular shape that surrounds the outer circumference of the wire 20B overall. The braided member 100B is provided, for example, so as to surround the outer circumference of the wire 20B over approximately the entire length in the length direction of the wire 20B. The braided member 100B is formed, for example, so as to surround the outer circumference of the wire 20B in each of the internal spaces of the corrugated tubes 40B and 50B. The braided member 100B is provided, for example, so as to surround the outer circumference of the wire member 25B, the electromagnetic wave absorbing member 80B, the restricting member 90B, and the braided member 100B between the corrugated tubes 40B and 50B. The braided member 100B is formed such that, for example, the outer shape of the portion covering the electromagnetic wave absorbing member 80B is larger than the outer shape of other portions.

### Configuration of Protective Member 60B)

The protective member 60B has, for example, a tubular shape that surrounds the outer circumference of the electromagnetic wave absorbing member 80B over the entire circumference in the circumferential direction. The protective member 60B functions as, for example, a waterproof cover for waterproofing the various members arranged inside the protective member 60B.

The protective member 60B includes, for example, a tubular connection tube portion 61 connected to the outer circumference of the corrugated tube 40B, a tubular connection tube portion 62 connected to the outer circumference of the corrugated tube 50B, and a main body tube portion 63 provided between the connection tube portion 61 and the connection tube portion 62. In the protective member 60B, for example, the connection tube portion 61 is fitted on the outer circumference of the corrugated tube 40B, and the connection tube portion 62 is fitted on the outer circumference of the corrugated tube 50B. The connection tube portion 61 is fastened from the outer circumferential side by the coupling member 65 and is fixed to the corrugated tube 40B. The connection tube portion 62 is fastened from the outer circumferential side by the coupling member 66 and is fixed to the corrugated tube 50B. The main body tube portion 63 is formed, for example, so as to surround the outer circumference of the wire 20B, the covering member 70B, the electromagnetic wave absorbing member 80B, the restricting member 90B, and the braided member 100B, which are exposed from the corrugated tubes 40B and 50B, over the entire circumference in the circumferential direction.

The protective member 60B is provided, for example, at a position spaced apart from the electromagnetic wave absorbing member 80A in the length direction of the wires 20A and 20B. The protective member 60B is provided, for example, at a position spaced apart from the protective member 60A in the length direction of the wires 20A and 20B.

Here, the protective member 60A is provided so as to overlap with a portion of the protective member 60B in a plan view from the first central axis direction of the electromagnetic wave absorbing member 80A, for example. For example, the main body tube portion 63 of the protective member 60A is provided so as to partially overlap with the main body tube portion 63 of the protective member 60B in a plan view from the first central axis direction. As shown in FIG. 3, the electromagnetic wave absorbing member 80A is provided so as to partially overlap with the protective member 60B in a plan view from the first central axis direction, for example. As shown in FIG. 4, the electromagnetic wave absorbing member 80B is provided so as to partially overlap with the protective member 60A in a plan view from the first central axis direction, for example.

### Configuration of Wire Harness 10

As shown in FIG. 2, the wire harness 10 has, for example, clamps 110A and 110B for fixing the conductive paths 15A and 15B to the vehicle body of the vehicle V (see FIG. 1). For example, the clamp 110B has the same structure as the clamp 110A For this reason, in the present embodiment, the clamp 110B is denoted by the same reference numerals as the clamp 110A, and detailed description of each of these elements will be omitted.

### Configuration of Clamps 110A and 110B

The clamps 110A and 110B are provided, for example, on the outer circumference of the conductive path 15A and the conductive path 15B. The clamps 110A and 110B are provided, for example, so as to fix the conductive path 15A and the conductive path 15B together. The clamps 110A and 110B are attached to the outer circumferential surfaces of the outer cover members 30A and 30B of the conductive paths 15A and 15B so as to maintain a state in which the conductive paths 15A and 15B are together, for example. For example, the clamp 110A is attached to the outer circumferential surface of the main body tube portion 63 of the protective member 60A surrounding the outer circumference of the electromagnetic wave absorbing member 80A and the outer circumferential surface of the corrugated tube 40B. The clamp 110A is provided so as to overlap with the electromagnetic wave absorbing member 80A in the radial direction of the wire 20A, for example. For example, the clamp 110B is attached to the outer circumferential surface of the main body tube portion 63 of the protective member 60B surrounding the outer circumference of the electromagnetic wave absorbing member 80B and the outer circumferential surface of the corrugated tube 50A. The clamp 110B is provided, for example, so as to overlap with the electromagnetic wave absorbing member 80B in the radial direction of the wire 20B.

As the material of the clamps 110A and 110B, for example, a resin material or a metal material can be used. As the resin material, for example, a resin material having conductivity or a resin material having no conductivity can be used. As the metal material, for example, an iron-based or aluminum-based metal material can be used.

### Configuration of Clamp 110A

As shown in FIG. 3, the clamp 110A has, for example, a holding portion 111 for holding the conductive paths 15A and 15B, and a fixing portion 112 fixed to the vehicle body. The clamp 110A is, for example, a single component in which the holding portion 111 and the fixing portion 112 are formed in one piece.

The holding portion 111 is formed, for example, so as to fix the protective member 60A to the conductive path 15B. The holding portion 111 is formed, for example, so as to surround the outer circumference of the main body tube portion 63 of the protective member 60A and the corrugated tube 40B. The holding portion 111 is formed, for example, so as to surround the outer circumference of the protective member 60A and the corrugated tube 40B over the entire circumference in the circumferential direction. For example, the holding portion 111 is formed in a tubular shape having a size capable of collectively surrounding the protective member 60A and the corrugated tube 40B.

The holding portion 111 covers, for example, the outer circumferential surface of the protective member 60A and covers the outer circumferential surface of the corrugated tube 40B. The holding portion 111 covers, for example, the outer circumferential surface of the main body tubular portion 63 of the protective member 60A along a portion of the outer circumferential surface thereof, and covers the outer circumferential surface of the corrugated tube 40B along a portion of the outer circumferential surface thereof. The holding portion 111 is formed such that the portion surrounding the outer circumference of the corrugated tube 40B has a smaller opening width than the portion surrounding the outer circumference of the main body tube portion 63, for example. The holding portion 111 covers, for example, the outer circumferential surface of the protective member 60A and the outer circumferential surface of the corrugated tube 40B so as to fasten them in the direction in which the conductive path 15A and the conductive path 15B approach each other. The conductive path 15A and the conductive path 15B are fixed together due to being fastened by the holding portion 111 in this manner. At this time, a portion of the outer circumferential surface of the main body tube portion 63 of the protective member 60A is in contact with, for example, the outer circumferential surface of the corrugated tube 40B.

The fixing portion 112 is formed so as to protrude from the outer circumferential surface of the holding portion 111 to the outside in the radial direction of the holding portion 111, for example. The fixing portion 112 is provided, for example, on the outer circumferential surface of the portion of outer circumferential surface of the holding portion 111 that surrounds the main body tube portion 63 of the protective member 60A. The fixing portion 112 is fixed to, for example, the vehicle body panel of the vehicle V (see FIG. 1). Due to the fixing portion 112 being fixed to the vehicle body panel, the conductive paths 15A and 15B held by the holding portion 111 are fixed to the vehicle body.

### Configuration of Clamp 110B

As shown in FIG. 4, the clamp 110B has, for example, a holding portion 111 for holding the conductive paths 15A and 15B, and a fixing portion 112 fixed to the vehicle body. The holding portion 111 of the clamp 110B is formed, for example, so as to fix the protective member 60B to the conductive path 15A. The holding portion 111 of the clamp 110B is formed, for example, so as to surround the outer circumference of the main body tube portion 63 of the protective member 60B and the corrugated tube 50A over the entire circumference in the circumferential direction. The holding portion 111 of the clamp 110B covers, for example, the outer circumferential surface of the main body tube portion 63 of the protective member 60B along a portion of the outer circumferential surface thereof, and covers the outer circumferential surface of the corrugated tube 50A along a portion of the outer circumferential surface thereof. The holding portion 111 of the clamp 110B, for example, covers the outer circumferential surface of the protective member 60B and the outer circumferential surface of the corrugated tube 50A so as to fasten them in the direction in which the conductive path 15A and the conductive path 15B approach each other. The conductive path 15A and the conductive path 15B are fixed together due to being fastened by the holding portion 111 in this manner. At this time, a portion of the outer circumferential surface of the main body tube portion 63 of the protective member 60B is in contact with, for example, the outer circumferential surface of the corrugated tube 50A.

The fixing portion 112 of the clamp 110B is provided, for example, on the outer circumferential surface of the portion of the outer circumferential surface of the holding portion 111 of the clamp 110B that surrounds the outer circumferential surface of the main body tube portion 63 of the protective member 60B.

Next, the actions and effects of this embodiment will be described.

(1) The wire harness 10 includes the conductive path 15A including the wire 20A, the ring-shaped electromagnetic wave absorbing member 80A having the through hole 81X through which the wire 20A passes, the conductive path 15B that includes the wire 20B and is provided side by side with the conductive path 15A, and the ring-shaped electromagnetic wave absorbing member 80B having the through hole 81Y through which the wire 20B passes. The electromagnetic wave absorbing member 80A is provided spaced apart from the electromagnetic wave absorbing member 80B in the length direction of the wire 20A.

According to this configuration, the electromagnetic wave absorbing member 80A is provided on the wire 20A, and the electromagnetic wave absorbing member 80B is provided on the wire 20B. That is, the electromagnetic wave absorbing members 80A and 80B are individually provided for the wires 20A and 20B, respectively. As a result, the electromagnetic waves to be reduced in each of the electromagnetic wave absorbing members 80A and 80B can be made smaller compared to the case where one electromagnetic wave absorbing member is provided for a plurality of wires. For this reason, compared to the case where one electromagnetic wave absorbing member is provided for a plurality of wires, each of the electromagnetic wave absorbing members 80A and 80B can be made more compact, and the mass of each of the electromagnetic wave absorbing members 80A and 80B can be reduced. As a result, if the electromagnetic wave absorbing members 80A and 80B vibrate due to traveling of the vehicle or the like, the loads respectively input from the electromagnetic wave absorbing members 80A and 80B to the wires 20A and 20B can be reduced. As a result, it is possible to suppress damage to the wires 20A and 20B caused by vibration of the electromagnetic wave absorbing members 80A and 80B.

(2) Also, the electromagnetic wave absorbing members 80A and 80B are individually provided for the wires 20A and 20B, respectively. For this reason, the shapes, installation positions, and the like of the electromagnetic wave absorbing members 80A and 80B can be individually set. As a result, the degree of freedom in designing the wire harness 10 can be improved compared to the case where one electromagnetic wave absorbing member is provided for a plurality of wires.

(3) The protective member 60A surrounding the outer circumference of the electromagnetic wave absorbing member 80A is provided so as to overlap with a portion of the protective member 60B surrounding the outer circumference of the electromagnetic wave absorbing member 80B in a plan view from the first central axis direction. As a result, it is possible to suppress an increase in the size of the wire harness 10.

(4) The clamp 110A for fixing the protective member 60A to the conductive path 15B was provided. According to this configuration, the protective member 60A surrounding the outer circumference of the electromagnetic wave absorbing member 80A is fixed to the conductive path 15B by the clamp 110A. As a result, the conductive path 15A and the conductive path 15B provided side by side with the conductive path 15A are integrated on the outer circumference of the electromagnetic wave absorbing member 80A. For this reason, the electromagnetic wave absorbing member 80A provided on the conductive path 15A can be held by the conductive path 15A and the conductive path 15B. As a result, the electromagnetic wave absorbing member 80A can be held more stably compared to the case where the electromagnetic wave absorbing member 80A is held by only the conductive path 15A. For this reason, it is possible to suppress vibration of the electromagnetic wave absorbing member 80A caused by vibration accompanying traveling of the vehicle or the like, and it is possible to suppress damage to the wire 20A caused by the vibration of the electromagnetic wave absorbing member 80A.

(5) The protective member 60A and the corrugated tube 40B are fastened by the clamp 110A, and the protective member 60A is fixed to the corrugated tube 40B. According to this configuration, the protective member 60A is interposed between the clamp 110A and the wire 20A, and the corrugated tube 40B is interposed between the clamp 110A and the wire 20B. As a result, a case is suppressed in which the clamp 110A comes into direct contact with the wires 20A and 20B. As a result, it is possible to prevent damage to the wires 20A and 20B caused by the fastening performed by the clamp 110A.

(6) The clamp 110B for fixing the protective member 60B to the conductive path 15A was provided. According to this configuration, the protective member 60B surrounding the outer circumference of the electromagnetic wave absorbing member 80B is fixed to the conductive path 15A by the clamp 110B. As a result, the conductive path 15A and the conductive path 15B provided side by side with the conductive path 15A are integrated on the outer circumference of the electromagnetic wave absorbing member 80B. For this reason, the electromagnetic wave absorbing member 80B provided on the conductive path 15B can be held by the conductive path 15A and the conductive path 15B. As a result, the electromagnetic wave absorbing member 80B can be held more stably compared to the case where the electromagnetic wave absorbing member 80B is held by only the conductive path 15B. Accordingly, it is possible to suppress vibration of the electromagnetic wave absorbing member 80B caused by vibration accompanying traveling of the vehicle or the like, and it is possible to suppress damage to the wire 20B caused by the vibration of the electromagnetic wave absorbing member 80B.

(7) The protective member 60B and the corrugated tube 50A are fastened by the clamp 110B, and the protective member 60B is fixed to the corrugated tube 50A. According to this configuration, the corrugated tube 50A is interposed between the clamp 110B and the wire 20A, and the protective member 60B is interposed between the clamp 110B and the wire 20B. As a result, a case is suppressed in which the clamp 110B comes into direct contact with the wires 20A and 20B. As a result, it is possible to suppress damage to the wires 20A and 20B caused by the fastening by the clamp 110B.

(8) The conductive paths 15A and 15B are fixed to the vehicle body by the clamp 110A. For this reason, the number of components can be reduced compared to the case where clamps are individually provided on both of the conductive paths 15A and 15B.

(9) Also, the electromagnetic wave absorbing member 80A can be stably held by the fixing force of the clamp 110A to the vehicle body. As a result, it is possible to further suppress vibration of the electromagnetic wave absorbing member 80A caused by vibration accompanying traveling of the vehicle or the like, and it is possible to further suppress damage to the wire 20A caused by vibration of the electromagnetic wave absorbing member 80A.

(10) The wire 20A is passed through the through hole 81X of the electromagnetic wave absorbing member 80A while being covered by the covering member 70A, and the wire 20B is passed through the through hole 81Y of the electromagnetic wave absorbing member 80B while being covered by the covering member 70B. For this reason, it is possible to suppress a case in which the inner circumferential surface of the through hole 81X comes into direct contact with the outer circumferential surface of the wire 20A, and it is possible to suppress a case in which the inner circumferential surface of the through hole 81Y comes into direct contact with the outer circumferential surface of the wire 20B. As a result, it is possible to suitably suppress damage to the wires 20A and 20B caused by contact with the inner circumferential surfaces of the through holes 81X and 81Y.

(11) The tape member 91 is formed so as to cover the outer circumferential surface of the electromagnetic wave absorbing member 80A, and the tape member 91 is provided between the electromagnetic wave absorbing member 80A and the braided member 100A. As a result, it is possible to suppress a case in which the electromagnetic wave absorbing member 80A comes into direct contact with the braided member 100A, and therefore it is possible to suitably suppress wearing of the braided member 100A caused by contact with the electromagnetic wave absorbing member 80A. As a result, damage to the braided member 100A can be suitably suppressed. As a result, it is possible to suppress deterioration of the electromagnetic shielding performance by the braided member 100A.

### Other Embodiments

The above-described embodiment can be implemented with the following modifications. The above-described embodiment and the following modified examples can be implemented in combination with each other as long as there are no technical contradictions.

In the above-described embodiment, the wire member 25A was arranged inside the through hole 81X of the electromagnetic wave absorbing member 80A so as to be in contact with the first portion 81A near the conductive path 15B and offset to the first portion 81A side. Also, the wire member 25B was arranged inside the through hole 81Y of the electromagnetic wave absorbing member 80B so as to be in contact with the third portion 81C near the conductive path 15A and offset to the third portion 81C side. However, the arrangement of the wire members 25A and 25B is not limited to this.

For example, the wire member 25A may also be arranged inside the through hole 81X of the electromagnetic wave absorbing member 80A so as to be in contact with the second portion 81B and offset to the second portion 81B side. The wire member 25A may also not be brought into contact with the first portion 81A and the second portion 81B inside the through hole 81X of the electromagnetic wave absorbing member 80A. For example, the wire member 25A may also be arranged inside the through hole 81X near the center of the through hole 81X.

For example, the wire member 25B may also be arranged inside the through hole 81Y of the electromagnetic wave absorbing member 80B so as to be in contact with the fourth portion 81D and offset to the fourth portion 81D side. The wire member 25B may also not be brought into contact with the third portion 81C and the fourth portion 81D inside the through hole 81Y of the electromagnetic wave absorbing member 80B. For example, the wire member 25B may also be arranged inside the through hole 81Y near the center of the through hole 81Y.

In the above-described embodiment, the tape member 91 of the restricting member 90A was wound so as to cover the end portion in the length direction of the covering member 70A, but there is no limitation to this. That is, in the above-described embodiment, the tape member 91 of the restricting member 90A was configured to be continuously wound with respect to the range from the outer circumferential surface of the electromagnetic wave absorbing member 80A to the outer circumferential surface of the wire 20A via the outer circumferential surface of the covering member 70A, but there is no limitation to this. For example, the tape member 91 of the restricting member 90A may also be wound so as to expose the end portion in the length direction of the covering member 70A. That is, the tape member 91 of the restricting member 90A may also be formed so as to be continuously wound around the range from the outer circumferential surface of the electromagnetic wave absorbing member 80A to the outer circumferential surface of the covering member 70A. Note that the tape member 91 of the restricting member 90B can also be changed in the same manner.

In the above-described embodiment, the restricting member 90A was formed by winding the tape member 91 so as to cover the entire outer circumferential surface of the electromagnetic wave absorbing member 80A. For example, the restricting member 90A may also be formed by winding the tape member 91 so as to cover only a portion of the outer circumferential surface of the electromagnetic wave absorbing member 80A.

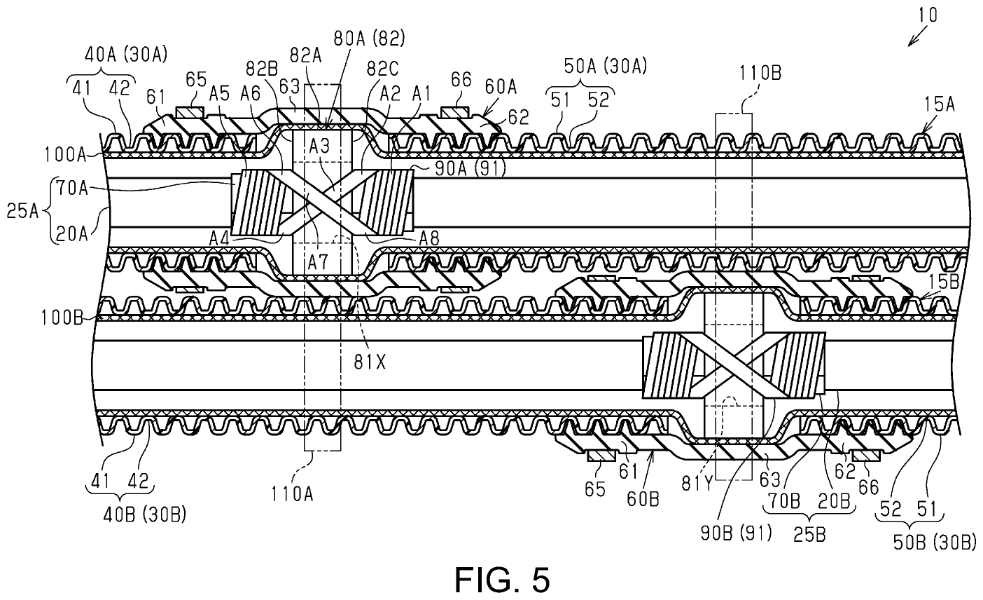

For example, as shown in FIG. 5, the restricting member 90A of this modified example integrally includes, for example, eight regions A1 to A8. The region A1 is a region in which the tape member 91 is wound around the wire member 25A of the portion led out from the through hole 81X of the electromagnetic wave absorbing member 80A to the corrugated tube 50A side. In the region A1, for example, the tape member 91 is wound a plurality of times around the entire circumference in the circumferential direction with respect to the covering member 70A surrounding the outer circumference of the wire 20A. The tape member 91 in the region A1 has, for example, a function of keeping the covering member 70A in a tubular state. The tape member 91 in the region A1 has, for example, an overlap winding structure.

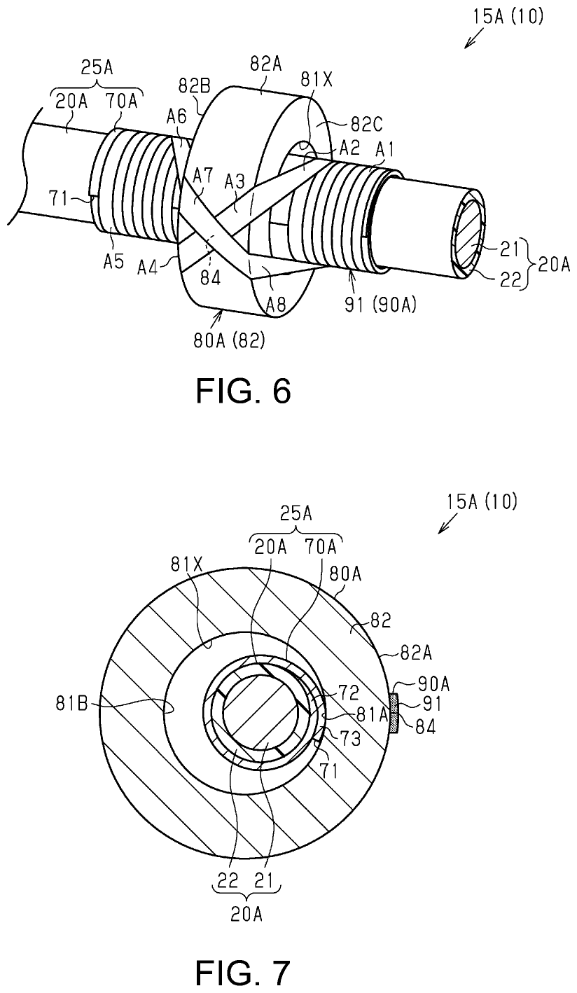

As shown in FIG. 6, the region A2 is a region connected to the region A1. The region A2 is, for example, a region in which the tape member 91 extends, in state of being tensioned with a tensile force, from the outer circumferential surface of the covering member 70A toward the outer circumferential surface 82A of the magnetic core 82 of the electromagnetic wave absorbing member 80A. The tape member 91 in the region A2 is provided so as to bridge between the outer circumferential surface of the covering member 70A and the outer circumferential surface 82A of the magnetic core 82. The tape member 91 in the region A2 is provided, for example, so as to oppose the side surface 82C of the magnetic core 82.

The region A3 is a region connected to the region A2. The region A3 is, for example, a region in which the tape member 91 is wound around the outer circumferential surface 82A of the magnetic core 82. The tape member 91 in the region A3 covers, for example, a portion of the outer circumferential surface 82A of the magnetic core 82. The tape member 91 in the region A3 is adhered to, for example, a portion of the outer circumferential surface 82A of the magnetic core 82.

As shown in FIG. 5, the region A4 is a region connected to the region A3. The region A4 is, for example, a region in which the tape member 91 extends, in a state of being tensioned with a tensile force, from the outer circumferential surface 82A of the magnetic core 82 toward the outer circumferential surface of the covering member 70A at the portion led out from the through hole 81X of the electromagnetic wave absorbing member 80A to the corrugated tube 40A side. The tape member 91 in the region A4 is provided so as to bridge between the outer circumferential surface 82A of the magnetic core 82 and the outer circumferential surface of the covering member 70A. The tape member 91 in the region A4 is provided, for example, so as to oppose the side surface 82B of the magnetic core 82.

The tape member 91 in the regions A2 to A4 is formed, for example, so as to intersect in the circumferential direction of the magnetic core 82 and to extend in an inclined manner so as to intersect in the length direction of the wire 20A. In the tape member 91 shown in FIG. 5, the starting end of the region A2 is located on the upper side in the drawing, and extends so as to incline downward in the drawing from the starting end of the region A2 toward the terminal end of the region A4.

The region A5 is a region connected to the region A4. The region A5 is a region in which the tape member 91 is wound around the wire member 25A at the portion led out from the through hole 81X of the electromagnetic wave absorbing member 80A to the corrugated tube 40A side. In the region A5, for example, the tape member 91 is wound a plurality of times around the entire circumference in the circumferential direction with respect to the covering member 70A surrounding the outer circumference of the wire 20A. The tape member 91 in the region A5 has, for example, a function of maintaining the covering member 70A in a tubular state. The tape member 91 in the region A5 has, for example, an overlap winding structure.

The region A6 is a region connected to the region A5. The region A6 is, for example, a region in which the tape member 91 extends, in a state of being tensioned with a tensile force, from the outer circumferential surface of the covering member 70A toward the outer circumferential surface 82A of the magnetic core 82. The tape member 91 in the region A6 is provided so as to bridge between the outer circumferential surface of the covering member 70A and the outer circumferential surface 82A of the magnetic core 82. The tape member 91 in the region A6 is provided, for example, so as to oppose the side surface 82B of the magnetic core 82.

The region A7 is a region connected to the region A6. The region A7 is, for example, a region in which the tape member 91 is wound around the outer circumferential surface 82A of the magnetic core 82. The tape member 91 in the region A7 is formed so as to intersect the tape member 91 in the region A3, for example. The tape member 91 in the region A7 covers, for example, a portion of the outer circumferential surface 82A of the magnetic core 82. The tape member 91 in the region A7 adheres to, for example, a portion of the outer circumferential surface 82A of the magnetic core 82 and adheres to a portion of the tape member 91 in the region A3.

The region A8 is a region connected to the region A7. The region A8 is, for example, a region in which the tape member 91 extends, in a state of being tensioned with a tensile force, from the outer circumferential surface 82A of the magnetic core 82 toward the region A1. The tape member 91 in the region A8 is provided so as to bridge between the outer circumferential surface 82A of the magnetic core 82 and the outer circumferential surface of the covering member 70A. The tape member 91 in the region A8 is provided, for example, so as to oppose the side surface 82C of the magnetic core 82.

The tape member 91 in the regions A6 to A8 is formed, for example, so as to intersect in the circumferential direction of the magnetic core 82 and to extend in an inclined manner so as to intersect in the length direction of the wire 20A. The tape member 91 in the regions A6 to A8 is formed so as to intersect the tape member 91 in the regions A2 to A4, for example. The tape member 91 in the regions A6 to A8 is formed so as to overlap with portions of the tape member 91 in the regions A2 to A4, for example. In the tape member 91 shown in FIG. 5, the starting end of the region A6 is located on the upper side in the drawing, and the tape member 91 extends toward the lower portion in the drawing from the starting end of the region A6 toward the terminal end of the region A8.

As shown in FIGS. 6 and 7, the tape member 91 is formed so as to adhere to, for example, the outer circumferential surface 82A of the magnetic core 82 in only a partial region 84 of the outer circumferential surface 82A. The tape member 91 is formed, for example, so as to adhere to only a region 84 that is smaller than half of the entire outer circumferential surface 82A of the magnetic core 82. The tape member 91 is formed, for example, so as to adhere to only a region 84 that is smaller than one-fourth of the entire outer circumferential surface 82A of the magnetic core 82. The tape member 91 is formed, for example, so as to adhere to only a region 84 that is smaller than one-fourth of the entire circumference in the circumferential direction of the outer circumferential surface 82A of the magnetic core 82.

At this time, as shown in FIG. 7, the tape member 91 may also be wound around the outer circumferential surfaces of the electromagnetic wave absorbing member 80A and the wire member 25A such that that the wire member 25A is arranged inside of the through hole 81X of the electromagnetic wave absorbing member 80A so as to be offset to a portion in the circumferential direction of the through hole 81X. For example, the wire member 25A is in contact with the first portion 81A and is separated from the second portion 81B inside the through hole 81X. Here, the first portion 81A with which the wire member 25A is brought into contact is provided at a position closer to the region 84, which is the outer circumferential surface of the electromagnetic wave absorbing member 80A covered by the tape member 91, than the second portion 81B in the direction intersecting the first central axis direction of the electromagnetic wave absorbing member 80A. The first portion 81A is, for example, the inner circumferential surface of the through hole 81X of the portion corresponding to the region 84 in the circumferential direction of the electromagnetic wave absorbing member 80A. For example, the first portion 81A is a portion located at the same angle as the region 84 of the outer circumferential surface 82A of the magnetic core 82 in the circumferential direction of the magnetic core 82. For example, the first portion 81A is a portion of the inner circumferential surface of the through hole 81X that is located on the underside of the region 84. The tape member 91 of this modification, for example, fixes the electromagnetic wave absorbing member 80A to the outer circumference of the wire member 25A such that the covering member 70A of the wire member 25A is arranged inside the through hole 81X so as to be in contact with the first portion 81A and offset to the first portion 81A side (region 84 side). Note that the wire member 25A is arranged, for example, offset in the same direction, that is, offset to the region 84 side, over the entire length in the first central axis direction of the through hole 81X. In other words, the tape member 91 is wound around the outer circumferential surfaces of the electromagnetic wave absorbing member 80A and the wire member 25A such that the wire member 25A is arranged offset in the same direction over the entire length in the first central axis direction of the through hole 81X.

According to this configuration, the tape member 91 is formed so as to cover only a portion in the circumferential direction of the outer circumferential surface 82A of the electromagnetic wave absorbing member 80A. This makes it possible to, for example, shorten the length of the tape member 91 compared to the case where the tape member 91 is formed so as to cover the outer circumferential surface 82A of the electromagnetic wave absorbing member 80A over the entire circumference in the circumferential direction. As a result, the manufacturing cost of the wire harness 10 can be reduced.

Note that the restricting member 90B can also be modified in the same manner as the restricting member 90A.

In the above-described embodiment, the restricting members 90A and 90B were constituted by the tape members 91, but there is no limitation to this. For example, metal bands or cable ties made of resin may also be used as the restricting members 90A and 90B.

In the above-described embodiment, the restricting member 90A was provided so as to fix the electromagnetic wave absorbing member 80A to the wire member 25A, but there is no limitation to this. For example, the shape and installation position of the restricting member 90A are not particularly limited as long as it is possible to restrict the relative movement of the electromagnetic wave absorbing member 80A with respect to the wire 20A in the length direction of the wire 20A. In the above-described embodiment, the restricting member 90A was formed so as to cover the outer circumferential surface of the electromagnetic wave absorbing member 80A, but it may also be formed so as not to surround the outer circumference of the electromagnetic wave absorbing member 80A. For example, the restricting member 90A may also be provided so as to be adjacent to the electromagnetic wave absorbing member 80A in the length direction of the wire 20A. Note that the restricting member 90B can also be modified in the same manner as the restricting member 90A.

In the above-described embodiment, the covering members 70A and 70B were embodied in structures including slits 71 that extend along the length direction of the wires 20A and 20B, but there is no limitation to this.

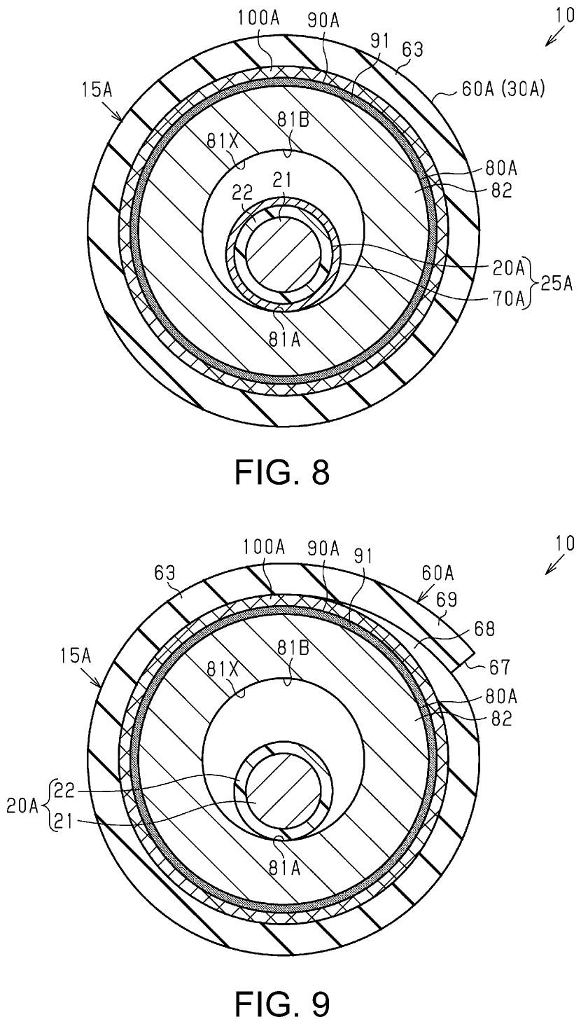

For example, as shown in FIG. 8, the covering member 70A may also be embodied in a cylindrical structure having no slit extending along the length direction of the wire 20A. The covering member 70A of this modified example is formed so as to surround the outer circumference of the wire 20A over the entire circumference in the circumferential direction. For example, the covering member 70A of this modification is already formed as a cylinder in the state before the wire 20A is arranged inside. Note that the covering member 70B can also be modified in the same manner.

In the above-described embodiment, the covering members 70A and 70B were embodied in twist tubes, but there is no limitation to this. The covering members 70A and 70B are not particularly limited as long as they are outer cover members capable of covering the outer circumferences of the wires 20A and 20B, and may be constituted by, for example, corrugated tubes. The corrugated tube in this case may or may not have a slit extending along the length direction of the wires 20A and 20B. Alternatively, the covering members 70A and 70B may also be embodied in a tape member wound around the outer circumferences of the wires 20A and 20B.

In the above-described embodiment, the end portions in the length direction of the covering members 70A and 70B were respectively accommodated in the internal spaces of the corrugated tubes 40A and 40B, but there is no limitation to this. For example, the end portions in the length direction of the covering members 70A and 70B may also be exposed from the corrugated tubes 40A and 40B.

In the above-described embodiment, the end portions in the length direction of the covering members 70A and 70B were accommodated in the internal spaces of the corrugated tubes 50A and 50B, but there is no limitation to this. For example, the end portions in the length direction of the covering members 70A and 70B may also be exposed from the corrugated tubes 50A and 50B.

For example, as shown in FIG. 9, the covering member 70A may also be omitted. In this case, the wire member 25A is constituted by only the wire 20A. At this time, a portion of the outer circumferential surface of the wire 20A is in contact with the first portion 81A, for example, inside the through hole 81X. Similarly, the covering member 70B may also be omitted. In this case, the wire member 25B is constituted by only the wire 20B.

In the above-described embodiment, the holding members 60A and 60B were embodied in endless structures, but there is no limitation to this. That is, in the above-described embodiment, the protective members 60A and 60B were embodied as already being formed as cylinders in the state before the electromagnetic wave absorbing members 80A and 80B are arranged inside, but there is no limitation to this.

For example, as shown in FIG. 9, the protective member 60A may also be embodied in a sheet-like structure having a slit 67 extending along the length direction of the wire 20A. The protective member 60A of this modified example is formed, for example, so as to have a tubular shape by winding a flexible sheet in the circumferential direction of the wire 20A. The protective member 60A has, for example, an end portion 68 in a second direction (in FIG. 9, the circumferential direction of the wire 20) intersecting the length direction of the wires 20A and 20B, and an end portion 69 on a side opposite to the end portion 68 in the second direction. The protective member 60A is formed so as to have a tubular shape, for example, by overlapping the end portion 68 and the end portion 69 in the radial direction of the electromagnetic wave absorbing member 80A. The inner circumferential dimension of the protective member 60A can be adjusted to match the outer circumferential dimension of the electromagnetic wave absorbing member 80A by, for example, adjusting the overlapping width between the end portion 68 and the end portion 69. The protective member 60A has elasticity according to which, for example, it is possible to return from a tubular state capable of surrounding the outer circumference of the electromagnetic wave absorbing member 80A to a sheet state of not surrounding the outer circumference of the electromagnetic wave absorbing member 80A.

The tubular state of the protective member 60A is maintained due to being fixed to the outer circumference of the corrugated tubes 40A and 50A by, for example, the coupling members 65 and 66 shown in FIG. 2. As the coupling members 65 and 66, for example, a tape member, a cable tie, a caulking band, or the like can be used.

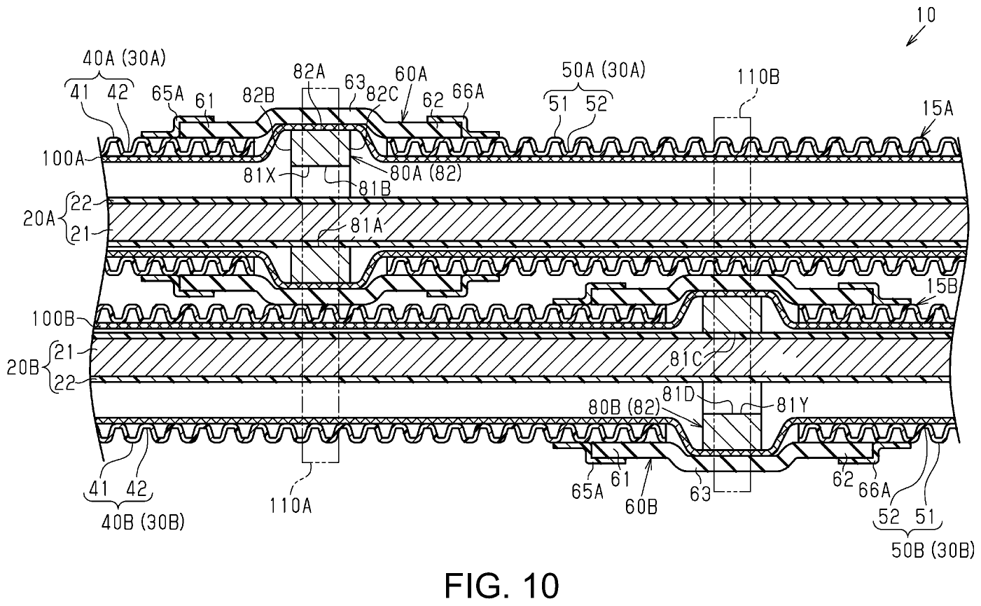

Next, a configuration used when tape members 65A and 66A are respectively used as the coupling members 65 and 66 will be described with reference to FIG. 10.

The tape member 65A is formed, for example, so as to fix the end portion in the length direction of the protective member 60A to the outer circumferential surface of the corrugated tube 40A. The tape member 66A is formed, for example, so as to fix the end portion in the length direction of the protective member 60A to the outer circumferential surface of the corrugated tube 50A.

The tape member 65A is wound, for example, over the outer circumferential surface of the end portion in the length direction of the protective member 60A and the outer circumferential surface of the corrugated tube 40A exposed from the protective member 60A. The tape member 65A is continuously wound around the range from the outer circumferential surface of the protective member 60A to the outer circumferential surface of the corrugated tube 40A, for example. The tape member 65A has, for example, an overlap winding structure. The tape member 65A is wound around the outer circumference of the end portion of the protective member 60A such that, for example, the tubular state of the protective member 60A is maintained.

The tape member 66A is wound, for example, over the outer circumferential surface of the end portion in the length direction of the protective member 60A and the outer circumferential surface of the corrugated tube 50A exposed from the protective member 60A. The tape member 66A is continuously wound around the range from the outer circumferential surface of the protective member 60A to the outer circumferential surface of the corrugated tube 50A. The tape member 66A has, for example, an overlap winding structure. The tape member 66A is wound around the outer circumference of the end portion of the protective member 60A such that, for example, the tubular state of the protective member 60A is maintained.

Note that the protective member 60B can also be modified similarly to the protective member 60A.

An adhesive layer or a pressure-sensitive adhesive layer may also be provided on one surface of the protective member 60A shown in FIG. 9. For example, an adhesive layer or a pressure-sensitive adhesive layer may be provided on one surface of the end portion 69 of the protective member 60A. According to this configuration, if the end portion 69 is overlapped with the end portion 68 of the protective member 60A, the end portion 69 can be adhered to the end portion 68 by an adhesive layer or a pressure-sensitive adhesive layer. As a result, it is possible to suitably suppress a case in which the protective member 60A returns to the sheet state at a stage before being fixed by the tape members 65A and 66A (see FIG. 10). Note that the protective member 60B can also be modified in the same manner.

As the material of the protective members 60A and 60B of the above-described embodiment, for example, a material having more excellent impact resistance and a more excellent cushioning property than the corrugated tubes 40A, 40B, 50A, and 50B can be used. For example, as the material of the protective members 60A and 60B, for example, a material having more excellent sound absorption than the corrugated tubes 40A, 40B, 50A, and 50B can be used. As the material of such protective members 60A and 60B, for example, a porous material can be used. As the material of the protective members 60A and 60B, for example, foamed resin can be used. The bubble structure in the foamed resin may be an open cell structure or a closed cell structure. As the material of the protective members 60A and 60B, for example, urethane foam, polyethylene foam, ethylene-propylene-diene rubber foam, or the like can be used. By using the material as described above as the material of the protective members 60A and 60B, the protective members 60A and 60B can function as cushioning members.

According to this configuration, the protective members 60A and 60B serving as cushioning members can be interposed between the electromagnetic wave absorbing members 80A and 80B and their circumferential components. This makes it possible to suppress the generation of abnormal noise caused by contact between the electromagnetic wave absorbing members 80A and 80B and the circumferential components.

For example, as shown in FIG. 10, the restricting members 90A and 90B may also be omitted. At this time, for example, by providing the clamp 110A, the relative movement of the electromagnetic wave absorbing member 80A with respect to the wire 20A can be restricted by the clamp 110A. Also, for example, by providing the clamp 110B, the relative movement of the electromagnetic wave absorbing member 80B with respect to the wire 20B can be restricted by the clamp 110B.

In the modified example shown in FIG. 10, the inner circumferential surface of the protective member 60A may be brought into contact with the outer circumferential surface of the braided member 100A, and the inner circumferential surface of the braided member 100A may be brought into contact with the outer circumferential surface 82A of the electromagnetic wave absorbing member 80A. Similarly, the inner circumferential surface of the protective member 60B may be brought into contact with the outer circumferential surface of the braided member 100B, and the inner circumferential surface of the braided member 100B may be brought into contact with the outer circumferential surface 82A of the electromagnetic wave absorbing member 80B.

In the above-described embodiment, the first fixing member was embodied in the vehicle body fixing clamp 110A, and the second fixing member was embodied in the vehicle body fixing clamp 110B, but there is no limitation to this. The structure of the clamp 110A is not particularly limited as long as the protective member 60A can be fixed to the corrugated tube 40B. For example, the fixing portion 112 may also be omitted from the clamp 110A. Also, the clamp 110A may be embodied in a tape member. The tape member in this case is wound around the outer circumferential surface of the protective member 60A and the outer circumferential surface of the corrugated tube 40B. Note that the clamp 110B can also be modified similarly to the clamp 110A.

The clamp 110A of the above-described embodiment may also be omitted.

The clamp 110B of the above-described embodiment may also be omitted.

In the above-described embodiment, the protective member 60A overlaps with a portion of the protective member 60B in a plan view from the first central axis direction of the electromagnetic wave absorbing member 80A, but there is no limitation to this. For example, the protective member 60A and the protective member 60B may not overlap each other in a plan view from the first central axis direction of the electromagnetic wave absorbing member 80A.

In the above-described embodiment, the first outer cover member (first outer cover) was embodied in the corrugated tube 40A, and the second outer cover member (second outer cover) was embodied in the corrugated tube 50A, but there is no limitation to this. For example, as the first outer cover member and the second outer cover member, a hard resin pipe, a metal pipe, or a rubber waterproof cover can be used. For example, the first outer cover member and the second outer cover member may be embodied in mutually different types of outer cover members.

In the above-described embodiment, the third outer cover member (third outer cover) was embodied in the corrugated tube 40B and the fourth outer cover member (fourth outer cover) was embodied in the corrugated tube 50B, but there is no limitation to this. For example, as the third outer cover member and the fourth outer cover member, a hard resin pipe, a metal pipe, or a rubber waterproof cover can be used. For example, the third outer cover member and the fourth outer cover member may also be embodied in mutually different types of outer cover members.

Instead of the braided members 100A and 100B of the above-described embodiment, another electromagnetic shielding member (electromagnetic shield) such as metal foil may be used.

The braided members 100A and 100B in the above-described embodiment may also be omitted.

The wires 20A and 20B of the above-described embodiment may also be changed to shielded wires.

The wires 20A and 20B of the above-described embodiment may also be changed to low-voltage wires.

In the above-described embodiment, the electromagnetic wave absorbing members 80A and 80B were constituted by only the magnetic cores 82, but there is no limitation to this. For example, the electromagnetic wave absorbing members 80A and 80B may also be configured to include a magnetic core 82 and a case for accommodating the magnetic core 82.

There is no particular limitation to the number and installation positions of the electromagnetic wave absorbing members 80A and 80B in the above-described embodiment. For example, two or more electromagnetic wave absorbing members 80A may also be provided for one wire 20A. For example, two or more electromagnetic wave absorbing members 80B may also be provided for one wire 20B. For example, the electromagnetic wave absorbing members 80A and 80B may be provided outside the vehicle interior, which is a waterproof region, or the electromagnetic wave absorbing members 80A and 80B may be provided inside the vehicle interior, which is a non-waterproof region.

In the above-described embodiment, there were two wires 20A and 20B of the wire harness 10, but there is no particularly limitation to this, and the number of wires 20A and 20B can be changed according to the specification of the vehicle V. For example, the wire harness 10 may have one wire or three or more wires. For example, it is also possible to use a configuration in which a low-voltage wire for connecting a low-voltage battery and various low-voltage devices (e.g., a lamp, car audio, etc.) are added as the wire of the wire harness 10.

The arrangement relationship between the inverter 11 and the high-voltage battery 12 in the vehicle V is not limited to the above-described embodiment, and may be appropriately changed according to the vehicle configuration.

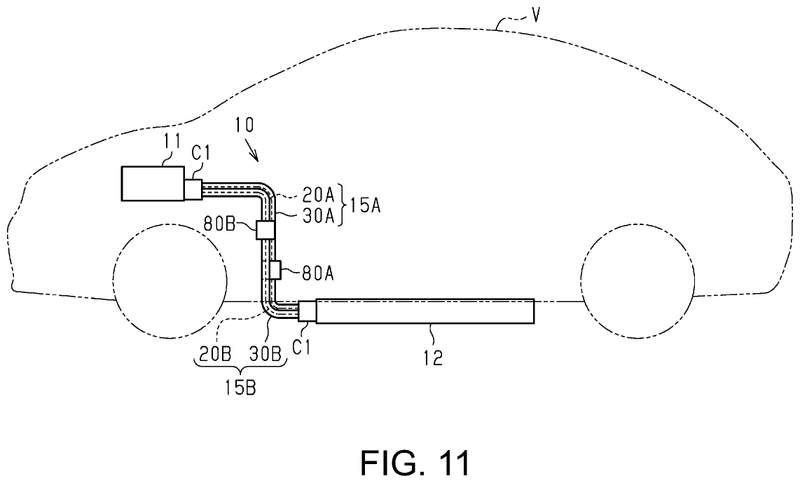

For example, as shown in FIG. 11, the high-voltage battery 12 may be arranged on approximately the entirety of the floor of the vehicle V and may be embodied in a wire harness 10 that electrically connects the high-voltage battery 12 and the inverter 11.

In the above-described embodiment, the inverter 11 and the high-voltage battery 12 were adopted as the electric devices connected by the wire harness 10, but there is no limitation to this. For example, the present disclosure may be adopted in a wire connecting the inverter 11 and the motor for driving the wheels. That is, the present disclosure is applicable as long as it electrically connects electric devices mounted in the vehicle V.

When the electromagnetic wave absorbing members 80A and 80B are viewed from the length direction of the wire harness 10 as in the embodiments of FIGS. 3 and 4, the central axis of one of the wires 20A may be eccentric with respect to the central axis of the corresponding electromagnetic wave absorbing member 80A, and the central axis of the other wire 20B may be eccentric with respect to the central axis of the corresponding electromagnetic wave absorbing member 80B. When the electromagnetic wave absorbing members 80A and 80B are viewed from the length direction of the wire harness 10 as in the embodiments of FIGS. 3 and 4, the distance between the central axis of one wire 20A and the central axis of the other wire 20B may be smaller than the distance between the central axis of the one electromagnetic wave absorbing member 80A and the central axis of the other electromagnetic wave absorbing member 80B.

In some cases, the electromagnetic wave absorbing member 80 of the embodiment is referred to as an electromagnetic noise filter attached to the wire 20 coaxially with the wire 20 at a predetermined position in the axial direction of the wire 20. In some cases, the predetermined position in the axial direction of the wire 20 to which the electromagnetic wave absorbing member 80 is attached is referred to as an electromagnetic noise filter attachment position.

As in the embodiment shown in the drawings, the opening terminal end portion of the first outer cover member 40A may be separated with a space from the opening terminal end portion of the second outer cover member 50A. The predetermined position in the axial direction of the wire 20A may be positioned in the axial direction gap formed between the opening terminal end portion of the first outer cover member 40A and the opening terminal end portion of the second outer cover member 50A. The opening terminal end portion of the first outer cover member 40A may face the side surface 82B of the electromagnetic wave absorbing member 80A, and the opening terminal end portion of the second outer cover member 50A may face the side surface 82C of the electromagnetic wave absorbing member 80A. The relationship between the wire 20A, the first outer cover member 40A, the second outer cover member 50A, and the electromagnetic wave absorbing member 80A may be applied to the relationship between the wire 20B, the first outer cover member 40B, the second outer cover member 50B, and the electromagnetic wave absorbing member 80B.

The protective member 60A of the embodiment shown in the drawings may be configured as a continuous tubular body that couples the opening terminal end portion of the first outer cover member 40A and the opening terminal end portion of the second outer cover member 50A such that the opening terminal end portion of the first outer cover member 40A and the opening terminal end portion of the second outer cover member 50A are spaced apart from each other by a gap in the axial direction. The protective member 60A of the illustrated embodiment may have a first tubular end portion configured to be attached to the outer surface in the radial direction of the opening terminal end portion of the first outer cover member 40A, a second tubular end portion configured to be attached to the outer surface in the radial direction of the opening terminal end portion of the second outer cover member 50A, and a tubular intermediate portion that extends between the first tubular end portion and the second tubular end portion. In one example, the tubular intermediate portion may be configured such that the gap in the axial direction formed between the opening terminal end portion of the first outer cover member 40A and the opening terminal end portion of the second outer cover member 50A is not exposed to the outside of the wire harness 10. In the embodiment shown in the drawings, the tubular intermediate portion of the protective member 60A may be configured to cover the entirety of the electromagnetic wave absorbing member 80A sandwiched between the opening terminal end portion of the first outer cover member 40A and the opening terminal end portion of the second outer cover member 50A, and the exposed portion of the braided member 100A that is not covered by the first outer cover member 40A and the second outer cover member 50A. The relationship between the wire 20A, the first outer cover member 40A the second outer cover member 50A, the protective member 60A, the electromagnetic wave absorbing member 80A, and the braided member 100A may also be applied to the relationship between the wire 20B, the first outer cover member 40B, the second outer cover member 50B, the protective member 60B, the electromagnetic wave absorbing member 80B, and the braided member 100B.

As in the embodiment shown in the drawings, the opening terminal end portion of the first outer cover member 40A may be separated with a space from the opening terminal end portion of the first outer cover member 40B in the axial direction of the wire harness 10, and the opening terminal end portion of the second outer cover member 50A may be separated with a space from the opening terminal end portion of the second outer cover member 50B in the axial direction of the wire harness 10. As in the embodiment shown in the drawings, the electromagnetic wave absorbing member 80A does not need to overlap with the electromagnetic wave absorbing member 80B in the axial direction of the wire harness 10, and the electromagnetic wave absorbing member 80A may be separated with a space from the electromagnetic wave absorbing member 80B in the axial direction of the wire harness 10. As in the embodiment shown in the drawings, the tubular intermediate portion of the protective member 60A may be separated with a space from the tubular intermediate portion of the protective member 60B in the axial direction of the wire harness 10. For example, as shown in FIG. 2, the wire harness 10 can have a wire multiplexing length portion that is a length range in which the wire member 25A and the wire member 25B are fixed side by side. The maximum thickness (maximum diameter) of the wire harness 10 in the wire multiplexing length portion may be smaller than the sum of the maximum thickness of the tubular intermediate portion of the protective member 60A and the maximum thickness of the tubular intermediate portion of the protective member 60B. The same applies to other examples as well.

In the embodiment, the overlapping between the end portion 72A and the end portion 73A of the covering member 70A may be non-adhesive overlapping, and for example, may be frictional overlapping. The covering member 70A may be referred to as a roll of elastically-resilient resin that is attached to a predetermined length position of one or more wires 20A. The same applies to the covering member 70B as well.

The embodiments disclosed herein are to be considered exemplary in all respects and not restrictive. The scope of the present disclosure is indicated by the scope of claims, not the above-mentioned meaning, and is intended to encompass all modifications within the meaning and range of equivalency to the claims.

1. A wire harness comprising:
a first conductive path including a first wire;
a ring-shaped first electromagnetic wave absorber including a first through hole through which the first wire passes;
a second conductive path that includes a second wire and is provided side by side with the first conductive path; and
a ring-shaped second electromagnetic wave absorber including a second through hole through which the second wire passes,
wherein the first electromagnetic wave absorber is provided spaced apart from the second electromagnetic wave absorber in a length direction of the first wire.

2. The wire harness according to claim 1, wherein:
the first conductive path further includes a first protective member surrounding an outer circumference of the first electromagnetic wave absorber,
the second conductive path further includes a second protective member surrounding an outer circumference of the second electromagnetic wave absorber, and
the first protective member is provided so as to overlap with a portion of the second protective member in a plan view from a first central axis direction in which a central axis of the first through hole extends.

3. The wire harness according to claim 2, further comprising a first fixing member for fixing the first protective member to the second conductive path.

4. The wire harness according to claim 3, further comprising a second fixing member for fixing the second protective member to the first conductive path.

5. The wire harness according to claim 4, wherein:
the first conductive path includes:
the first wire;
a first outer cover accommodating the first wire; and
a second outer cover that accommodates the first wire and is provided spaced apart from the first outer cover in the length direction of the first wire,
the first protective member is provided so as to bridge between an outer circumference of the first outer cover and an outer circumference of the second outer cover, and
the second fixing member fixes the second protective member to the second outer cover by fastening the second protective member and the second outer cover.

6. The wire harness according to claim 3, wherein:
the second conductive path includes:
the second wire;
a third outer cover accommodating the second wire; and
a fourth outer cover that accommodates the second wire and is provided spaced apart from the third outer cover in a length direction of the second wire,
the second protective member is provided so as to bridge between an outer circumference of the third outer cover and an outer circumference of the fourth outer cover, and
the first fixing member fixes the first protective member to the third outer cover member by fastening the first protective member and the third outer cover.

7. The wire harness according to claim 3, wherein the first fixing member is a vehicle body fixing clamp for fixing the first conductive path to a vehicle body.

8. The wire harness according to claim 1, wherein:
the first conductive path further includes a first cover that covers an outer circumference of the first wire,
the second conductive path further includes a second cover that covers an outer circumference of the second wire,
the first cover passes through the first through hole while covering the outer circumference of the first wire, and
the second cover passes through the second through hole while covering the outer circumference of the second wire.

9. The wire harness according to claim 1, wherein:
the first conductive path further includes a first electromagnetic shield that surrounds an outer circumference of the first wire,
the second conductive path further includes a second electromagnetic shield that surrounds an outer circumference of the second wire,
the first electromagnetic shield is provided so as to surround an outer circumference of the first electromagnetic wave absorber, and
the second electromagnetic shield is provided so as to surround an outer circumference of the second electromagnetic wave absorber.
